(19) United States
(12) Patent Application Publication
(10) Pub. No.: US 2007/0114618 A1
(43) Pub. Date: May 24, 2007

(54) Semiconductor device and method of manufacturing the same

(76) Inventor: Mizuki Ono, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/511,296

(22) Filed: Aug. 29, 2006

(30) Foreign Application Priority Data
Nov. 21, 2005 (JP) 2005-336062

(51) Int. Cl. H01L 29/94

(52) U.S. Cl. 257/410

(57) ABSTRACT

It is made possible to provide a highly-reliable, high-performance semiconductor device that reduces the intensity of the electric field in the gate insulating film, has a higher current driving force, and can operate at a high speed. A semiconductor device includes: a semiconductor region provided on a substrate; source and drain regions provided in the semiconductor region at a distance from each other so as to face each other; a semiconductor layer provided on the source and drain regions and a region interposed between the source region and the drain region; a gate insulating film provided at least above the region interposed between the source region and the drain region so as to sandwich the semiconductor layer between the gate insulating film and the region interposed between the source region and the drain region; and a gate electrode provided on the gate insulating film.

### CROSS-REFERENCE TO RELATED APPLICATION

This application is based upon and claims the benefit of priority from prior Japanese Patent Application No. 2005-336062 filed on Nov. 21, 2005 in Japan, the entire contents of which are incorporated herein by reference.

### BACKGROUND OF THE INVENTION

1. Field of the Invention

The present invention relates to a semiconductor device and a method of manufacturing the semiconductor device.

2. Related Art

In conventional semiconductor devices, an antinomy exists in that the source and drain regions are required to be shallow so as to suppress the short channel effect while being required to have low resistance so as to reduce the parasitic resistance. To counter this problem, so-called Schottky field effect transistors in which the source and drain regions are formed with a material such as a metal or a metal silicide have been developed.

On the other hand, to increase the controllability of the gate electrode over the potential of the channel region, the equivalent oxide thickness of the gate insulating film, or the value obtained by dividing the product of the thickness of the insulating film and the silicon oxide permittivity by the permittivity of the insulating film (the value will be hereinafter referred to also as the EOT (Equivalent Oxide Thickness)), is required to be smaller. Also, to reduce leakage current flowing to the gate electrode through the gate insulating film, the thickness of the gate insulating film is required to be smaller. So as to satisfy these requirements, the use of a material (a high-k material) with a higher permittivity than the permittivity of the conventional silicon oxide as the material for the gate insulating film has been considered.

Accordingly, while the use of metal as the material for the source and drain regions has been considered, the use of a high permittivity material as the material for the gate insulating film has also been considered (see “Low temperature MOSFET technology with Schottky barrier source/drain, high-K gate dielectric and metal gate electrode”, Shiyang Zhu et al., Solid-State Electronics vol. 48 (2004), pp. 1987-1992, for example). A layer made of silicon oxide, silicon nitride, or silicon oxynitride may be formed at the interface between the channel region and the insulating film made of a high-k material, as so to lower the interface level at the interface between the gate insulating film and the channel. In this manner, the use of a stacked insulating film as the gate insulating film has been considered. By providing a layer made of a low permittivity material between the channel region and the insulating film made of a high permittivity material, capacitive coupling between the source region and the channel region via the gate insulating film is suppressed, and accordingly, it is prevented that the potential of the channel region approaches the potential of the source region. Thus, a decrease in current driving force can be effectively prevented.

The use of a stacked gate insulating film consisting of a low permittivity film made of a low permittivity material formed closer to the substrate surface and a high permittivity film made of a high permittivity material provided on the low permittivity film suppresses the current flowing through the gate insulating film, and also increases the controllability of the gate electrode over the potential of the channel region. Furthermore, the use of such a stacked gate insulating film has the advantage that the interface between the gate insulating film and the substrate can be improved, and a decrease in current driving force due to the capacitive coupling between the source region and the channel region via the gate insulating film can be prevented.

In such a case, however, the electric field in the low permittivity film becomes very intensive due to the continuity of the flux density at the interface between the materials that differ from each other in permittivity. Especially in a Schottky field effect transistor in which the source and drain regions are made of a metal or a metal silicide, and a stacked gate insulating film is employed for the gate insulating film, the electric field intensity in the low permittivity insulating film in the vicinities of the corners of the source and drain regions is very high. In a Schottky field effect transistor, the resistance of the Schottky barrier formed at the interface between the channel region and the source and drain region adversely affect the current driving force, resulting in the difficulty of achieving a sufficiently high current driving force. This problem greatly hinders high-speed operations and improvement in reliability of devices.

### SUMMARY OF THE INVENTION

The present invention has been made for solving the above problems, and an object thereof is to provide a highly-reliable, high-performance semiconductor device that reduces the intensity of the electric field in the gate insulating film, has a higher current driving force, and can operate at a high speed.

A semiconductor device according to a first aspect of the present invention include: a semiconductor region provided on a substrate; source and drain regions provided in the semiconductor region at a distance from each other so as to face each other; a semiconductor layer provided on the source and drain regions and a region interposed between the source region and the drain region; a gate insulating film provided at least above the region interposed between the source region and the drain region so as to sandwich the semiconductor layer between the gate insulating film and the region interposed between the source region and the drain region; and a gate electrode provided on the gate insulating film.

A semiconductor device according to a second aspect of the present invention include:

a first semiconductor element that includes: a first semiconductor region that is formed on a semiconductor substrate and contains p-type impurities; first source and drain regions that is formed so as to face each other at a distance from each other in the first semiconductor region, and are made of a metal such as Ni (nickel) or Co (cobalt) or a metal silicide of Ni (nickel) or Co (cobalt); a first semiconductor layer that is formed on the first source and drain regions and a region interposed between the first source region and the first drain region; a first gate insulating film that is formed at least above the region interposed between the first source region and the first drain region so as to sandwich the first semiconductor layer between the first gate insulating film and the region interposed between the first source region and the first drain region; and a first gate electrode that is disposed on the first gate insulating film; and

a second semiconductor element that includes: a second semiconductor region that is formed on a semiconductor substrate and contains n-type impurities; second source and drain regions that is formed so as to face each other at a distance from each other in the second semiconductor region, and are made of a metal such as Ni (nickel) or Co (cobalt) or a metal silicide of Ni (nickel) or Co (cobalt); a second semiconductor layer that is formed on the second source and drain regions and a region interposed between the second source region and the second drain region; a second gate insulating film that is formed at least above the region interposed between the second source region and the second drain region so as to sandwich the second semiconductor layer between the second gate insulating film and the region between the second source region and the second drain region; and a second gate electrode that is disposed on the second gate insulating film.

A method of manufacturing a semiconductor device according to a third aspect of the present invention includes: introducing either n-type impurities or p-type impurities into a semiconductor region; forming source and drain regions at a distance from each other, so that the source and drain regions face each other in the semiconductor region into which the impurities are introduced; forming a semiconductor layer to cover at least a region interposed between the source and drain regions; forming a gate insulating film on the semiconductor layer; and forming a gate electrode on the gate insulating film.

A method of manufacturing a semiconductor device according to a fourth aspect of the present invention includes: introducing either n-type impurities or p-type impurities into a semiconductor region having a {111} plane; forming a first insulating film above the semiconductor region; forming a gate electrode at least on a part of the first insulating film; forming a gate insulating film by removing portions of the first insulating film located on both sides of the gate electrode; partially removing surfaces on both side faces of the gate electrode in the semiconductor region; forming a second insulating film on both sides of the gate electrode; forming voids by removing at least a part of the semiconductor region through anisotropic etching; and forming source and drain regions in the voids.

A method of manufacturing a semiconductor device according to a fifth aspect of the present invention include: introducing either n-type impurities or p-type impurities into a semiconductor layer of a SOI substrate on which the semiconductor layer is formed on a supporting substrate via a first insulating film; forming a second insulating film on the semiconductor layer; forming a gate electrode on at least a part of the second insulating film; removing portions of the second insulating film located on both sides of the gate electrode; forming a third insulating film on side faces of the gate electrode; removing portions of the semiconductor layer located on both sides of the gate electrode; forming voids by removing at least a part of the first insulating film; and forming source and drain regions in the voids.

### BRIEF DESCRIPTION OF THE DRAWINGS

FIG. 1 is a cross-sectional view of a semiconductor device according to a first embodiment of the present invention;

FIG. 2 is a cross-sectional view of a semiconductor device shown as a comparative example of the first embodiment;

FIG. 3 is a diagram showing the electric field intensity in the gate insulating film in each of the first embodiment and the comparative example;

FIG. 4 is a diagram showing the current driving force of the semiconductor device of each of the first embodiment and the comparative example;

FIG. 5 is a diagram showing the current density flowing through the side faces of the source region in the semiconductor device of each of the first embodiment and the comparative example;

FIG. 6 is a diagram showing the current density flowing through the upper face of the source region in the semiconductor device of the first embodiment;

FIG. 7 is a cross-sectional view for explaining the structure of a semiconductor device as another comparative example in which the gate electrode is embedded in the substrate;

FIG. 8 is a characteristic diagram showing the dependence of the electric field intensity on the thickness of the semiconductor layer;

FIG. 9 is a characteristic diagram showing the dependence of the drain current on the thickness of the semiconductor layer;

FIG. 10 is a cross-sectional view of a semiconductor device according to a second embodiment of the present invention;

FIG. 11 is a cross-sectional view illustrating a step in the process of manufacturing the semiconductor device according to the second embodiment;

FIG. 12 is a cross-sectional view illustrating a step in the process of manufacturing the semiconductor device according to the second embodiment;

FIG. 13 is a cross-sectional view illustrating a step in the process of manufacturing the semiconductor device according to the second embodiment;

FIG. 14 is a cross-sectional view illustrating a step in the process of manufacturing the semiconductor device according to the second embodiment;

FIG. 15 is a cross-sectional view illustrating a step in the process of manufacturing the semiconductor device according to the second embodiment;

FIG. 16 is a cross-sectional view of a semiconductor device according to a third embodiment of the present invention;

FIG. 17 is a cross-sectional view illustrating a step in the process of manufacturing the semiconductor device according to the third embodiment;

FIG. 18 is a cross-sectional view illustrating a step in the process of manufacturing the semiconductor device according to the third embodiment;

FIG. 19 is a cross-sectional view illustrating a step in the process of manufacturing the semiconductor device according to the third embodiment;

FIG. 20 is a cross-sectional view of a semiconductor device according to a fourth embodiment of the present invention;

FIG. 21 is a cross-sectional view illustrating a step in the process of manufacturing the semiconductor device according to the fourth embodiment;

FIG. 22 is a cross-sectional view illustrating a step in the process of manufacturing the semiconductor device according to the fourth embodiment;

FIG. 23 is a cross-sectional view illustrating a step in the process of manufacturing the semiconductor device according to the fourth embodiment;

FIG. 24 is a cross-sectional view illustrating a step in the process of manufacturing the semiconductor device according to the fourth embodiment;

FIG. 25 is a cross-sectional view illustrating a step in the process of manufacturing the semiconductor device according to the fourth embodiment;

FIG. 26 is a cross-sectional view of a semiconductor device according to a fifth embodiment of the present invention;

FIG. 27 is a cross-sectional view illustrating a step in the process of manufacturing the semiconductor device according to the fifth embodiment;

FIG. 28 is a cross-sectional view illustrating a step in the process of manufacturing the semiconductor device according to the fifth embodiment;

FIG. 29 is a cross-sectional view illustrating a step in the process of manufacturing the semiconductor device according to the fifth embodiment;

FIG. 30 is a cross-sectional view illustrating a step in the process of manufacturing the semiconductor device according to the fifth embodiment;

FIG. 31 is a cross-sectional view illustrating a step in the process of manufacturing the semiconductor device according to the fifth embodiment;

FIG. 32 is a perspective view of a semiconductor device according to a sixth embodiment of the present invention;

FIG. 33 is a cross-sectional view of the semiconductor device of the sixth embodiment, taken along the plane indicated by the broken line in FIG. 32;

FIG. 34 is a perspective view illustrating a step in the process of manufacturing the semiconductor device according to the sixth embodiment;

FIG. 35 is a perspective view illustrating a step in the process of manufacturing the semiconductor device according to the sixth embodiment;

FIG. 36 is a perspective view illustrating a step in the process of manufacturing the semiconductor device according to the sixth embodiment;

FIG. 37 is a perspective view illustrating a step in the process of manufacturing the semiconductor device according to the sixth embodiment;

FIG. 38 is a perspective view of a semiconductor device according to a seventh embodiment of the present invention;

FIG. 39 is a cross-sectional view of the semiconductor device of the seventh embodiment, taken along the plane indicated by the broken line in FIG. 38;

FIG. 40 is a perspective view illustrating a step in the process of manufacturing the semiconductor device according to the seventh embodiment;

FIG. 41 is a perspective view illustrating a step in the process of manufacturing the semiconductor device according to the seventh embodiment; and

FIG. 42 is a perspective view illustrating a step in the process of manufacturing the semiconductor device according to the seventh embodiment.

### DETAILED DESCRIPTION OF THE INVENTION

The following is a description of embodiments of the present invention, with reference to the accompanying drawings. It should be noted that the present invention is not limited to the following embodiments, but various changes and modification may be made to them.

### First Embodiment

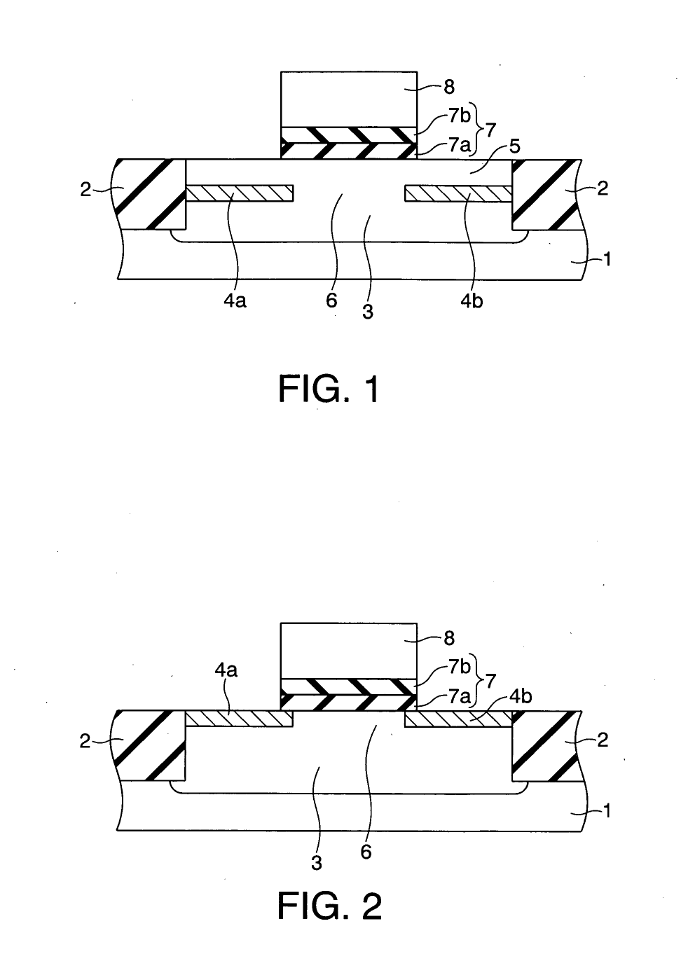

FIG. 1 is a schematic cross-sectional view of a semiconductor device according to a first embodiment of the present invention. The semiconductor device of this embodiment is a Schottky field effect transistor that is formed in a semiconductor region 3 of a semiconductor substrate 1. The semiconductor region 3 is isolated by a device isolating region 2, and contains p-type impurities. In the semiconductor region 3, a source region 4a and a drain region 4b made of metal or metal silicide are disposed at a distance from each other, so that the end portions of both regions 4a and 4b face each other. A semiconductor layer 5 is disposed over the source region 4a, the drain region 4b, and the region between the source region 4a and the drain region 4b. The portion of the semiconductor layer 5 located above the region between the source region 4a and the drain region 4b serves as a channel region 6. A gate insulating film 7 is disposed on the channel region 6. The gate insulating film 7 has a stacked structure formed with a low permittivity insulating film 7a made of a low permittivity material on the side of the channel region 6, and a high permittivity insulating film 7b provided on the low permittivity insulating film 7a. A gate electrode 8 is disposed on the gate insulating film 7. The gate electrode 8 has regions overlapping the source region 4a and the drain region 4b. When seen from the source region 4a and the drain region 4b, the end portions of the source region 4a and the drain region 4b are designed to be partially located in the regions below the gate electrode 8.

In a gate insulating film, a strong electric field is normally induced in the vicinity of the ends of the source and drains regions. Particularly, a very strong electric field is induced in the vicinity of the end of the source region. This trend is particularly noted in a Schottky field effect transistor having the source and drain regions made of metal or metal silicide, and is even more noted in a case where the gate insulating film is made of a low permittivity material on the substrate side while being made of a high permittivity material on the gate electrode side.

As a comparative example to be compared with this embodiment, FIG. 2 illustrates an n-type Schottky field effect transistor. The Schottky field effect transistor of this comparative example has the same structure as this embodiment, except that the semiconductor layer 5 is removed, and the gate insulating film 7 is in direct contact with the source region 4a and the drain region 4b.

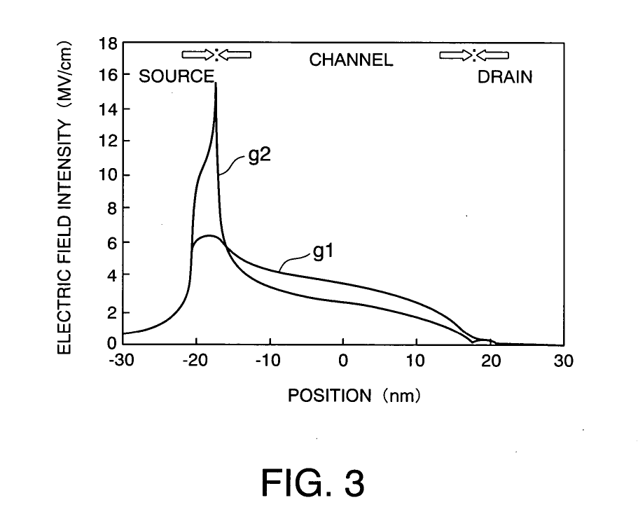

The electric field intensity in the gate insulating film 7 of each of the Schottky field effect transistors of this embodiment and the comparative example was calculated through a simulation. The calculation results are shown in FIG. 3. Graph g1 in FIG. 3 represents the electric field intensity in the gate insulating film of this embodiment, and graph g2 represents the electric field intensity in the gate insulating film of the comparative example. Here, each of the Schottky field effect transistors of this embodiment and the comparative example is an n-type device of 35 nm in channel length that has the source and drain regions 4a and 4b made of metal. The depth of each of the source and drain regions 4a and 4b is 10 nm, and each length of the right and left overlapping portions between the gate electrode 8 and the source and drain regions 4a and 4b is 3 nm. The relative permittivity of the insulating film 7a of the gate insulating film 7 on the substrate side is 3.9, and the EOT is 0.3 nm. The relative permittivity of the insulating film 7b of the gate insulating film 7 on the gate electrode side is 20, and the EOT is 0.7 nm. As for the voltage conditions, the source potential and the substrate potential are both 0 V, and the drain potential and the gate potential are both 1 V. The abscissa axis in FIG. 3 indicates the location along the substrate surface, where 0 nm is equivalent to the center of the channel, the region between −17.5 nm and 17.5 nm is the channel region, the region at the left of the channel region is the source region 4a, and the region at the right of the channel region is the drain region 4b. The ordinate axis indicates the electric field intensity in the gate insulating film at the interface between the gate insulating film and the substrate. However, the electric field at the interface is discontinuous, as the gate insulating film and the substrate differ from each other in permittivity. In view of this, FIG. 3 shows the value of the electric field intensity in the position 0.05 nm inward to the gate insulating film. As can be seen from graph g2 in FIG. 3, the electric field intensity in the gate insulating film of the comparative example exhibits a very large value at the end of the source region (at the point of −17.5 nm on the abscissa).

In this embodiment, on the other hand, the electric field intensity is much lower than that of the comparative example. More specifically, while the largest value of the electric field intensity in the Schottky field effect transistor of the comparative example is approximately 15.6 MV/cm, the largest value of the electric field intensity in the Schottky field effect transistor of this embodiment is approximately 6.46 MV/cm, which is almost 41% of that of the comparative example. Accordingly, it becomes apparent that the structure of this embodiment is very effective in reducing the electric field intensity in the gate insulating film.

The reason why the electric field in the gate insulating film is restrained in the Schottky field effect transistor of this embodiment is that the gate insulating film 7 is at a distance from the ends of the source and drain regions 4a and 4b. Since the electric field intensity becomes very high in the vicinities of the ends of the source and drain regions 4a and 4b, the gate insulating film 7 is formed at a distance from the source and drain regions 4a and 4b in the Schottky field effect transistor of this embodiment. In this structure, the gate insulating film 7 does not exist in the vicinities of the ends of the source and drain regions 4a and 4b in which the electric field intensity becomes very high. In this manner, the electric field intensity in the gate insulating film 7 can be made very low. This fact was newly found by the inventor of the present invention.

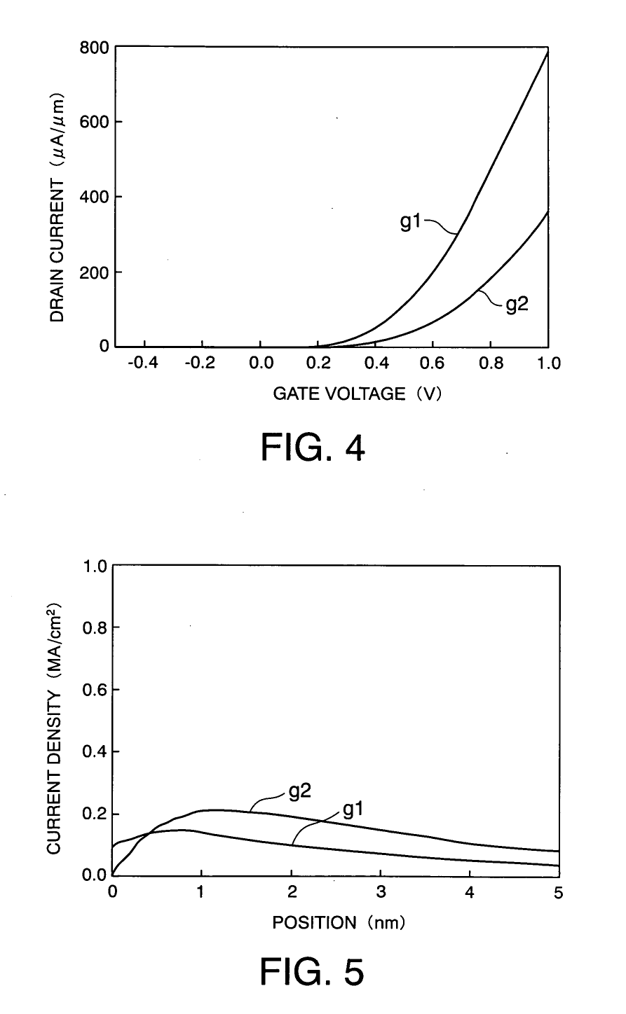

Referring now to FIG. 4, the current driving forces of the Schottky field effect transistors of this embodiment and the comparative example are described. In FIG. 4, graph g1 represents the characteristics of the drain current in relation to the gate voltage of the transistor of this embodiment, and graph g2 represents the characteristics of the drain current in relation to the gate voltage of the transistor of the comparative example. In FIG. 4, the abscissa axis indicates the gate voltage, and the ordinate axis indicates the value per unit width of the drain current flowing in each transistor. The drain voltage is 1 V, and the potentials of the source region 4a and the substrate 1 are both 0 V.

As can be seen from FIG. 4, the current driving force of the transistor of this embodiment is much larger than that of the transistor of the comparative example. More specifically, the current value with the gate voltage of 1 V is approximately 352 μA/μm in the comparative example, while it is approximately 785 μA/μm in this embodiment, which is about 223% larger. This teaches that the use of the structure of this embodiment is very effective in increasing the current driving force.

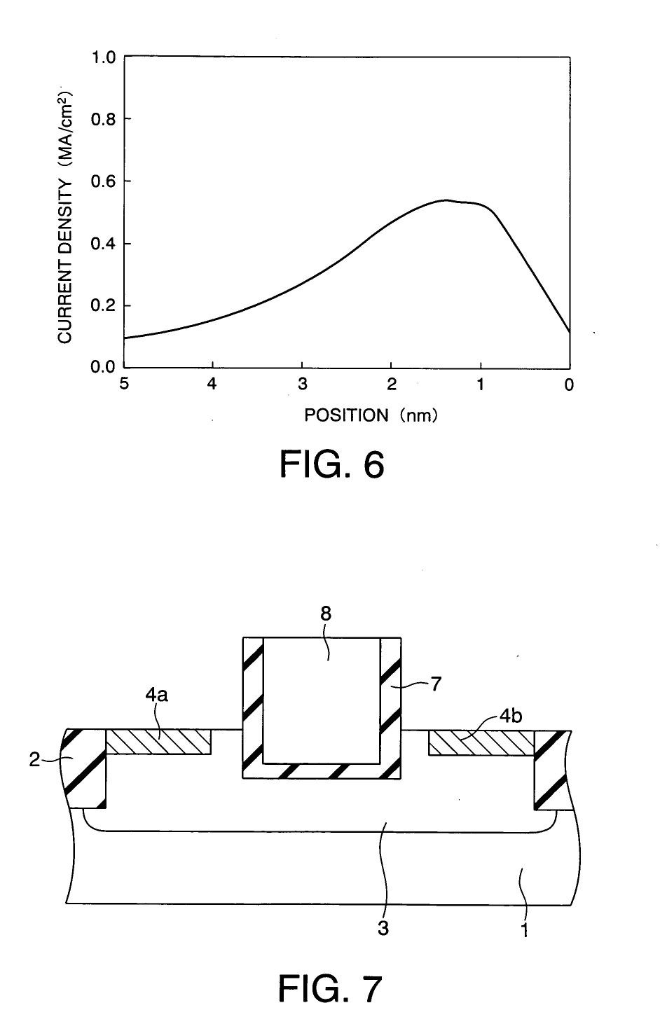

The current driving force in the transistor of this embodiment is larger because the current can flow in and out not only through the side faces of the source and drain regions 4a and 4b but also through the upper faces of the source and drain regions 4a and 4b. To explain this, FIG. 5 shows graph g1 and graph g2 representing the characteristics of the value per unit area (the current density) of the current flowing through the side face of the source region 4a in each of the transistors of this embodiment and the comparative example, and FIG. 6 shows the current density of the current flowing through the upper face of the source in the transistor of this embodiment. In each of FIGS. 5 and 6, the ordinate axis indicates the value of the density of the current flowing through the side face and the upper face of each source region 4a. The abscissa axis in FIG. 5 indicates the depth measured along the side face of the source region 4a from the upper face of the source region 4a. The abscissa axis in FIG. 6 indicates the length measured along the upper face of the source region 4a from the channel-side end of the source region 4a. The abscissa axis in FIG. 6 has the right-side end of the source region 4a serving as the point of origin, and the value increases from right to left on the abscissa axis. As shown in FIG. 5, the value of the current flowing through the side face of the source region 4a in the transistor of this embodiment is substantially equal to that in the transistor of the comparative example. On the other hand, the current flowing through the upper face of the source region 4a in the transistor of this embodiment is much higher than the current flowing through the side face of the source region 4a in the transistor of this embodiment, as shown in FIG. 6.

As a high current flows through the upper face of the source region 4a in the transistor of this embodiment, the transistor of this embodiment can obtain much larger current driving force than the transistor of the comparative example. The reason for this can be considered as follows. In the transistor of this embodiment, the upper face of the source region 4a faces the gate electrode 8. Accordingly, the potential of the semiconductor layer 5 located above the source region 4a is affected by the potential of the gate electrode 8, so as to approach the potential of the gate electrode 8. As a result, the Schottky barrier at the Schottky junction formed at the interface between the source region 4a and the semiconductor layer 5 becomes thinner, and the resistance is lowered to allow a high current to flow through the upper face of the source region 4a. This fact was also newly found by the inventor.

As described above, to obtain large current driving force in the structure of this embodiment, it is essential that the Schottky barrier on the upper face of the source region 4a is thin by virtue of the control on the gate electrode 8. Therefore, there should be overlapping portions between the gate electrode 8 and the source and drain regions 4a and 4b.

In this manner, this embodiment provides a Schottky field effect transistor in which the resistance of the source and drain regions 4a and 4b is low, and high current driving force can be obtained while an electric field in the gate insulating film is reduced. In this structure, the gate insulating film 7 has a stacked structure of the insulating film 7a made of silicon oxide or the like and the insulating film 7b made of a high permittivity material. The insulating film 7a made of silicon oxide or the like improves the interface with the substrate, and restricts a decrease in current driving force due to the capacitive coupling between the channel region 6 and the source region 4a via the gate insulating film 7. The insulating film 7b made of a high permittivity material restricts the current flowing through the gate insulating film, and improves the controllability of the gate electrode 8 over the potential of the channel region 6. Accordingly, the electric field in the gate insulating film is restrained, and higher current driving force can be achieved. Thus, a high-performance semiconductor device that can operate at a high speed and exhibit high reliability can be achieved.

So as to reduce the resistance of the Schottky junction formed at the interface between the channel region 6 and the source and drain regions 4a and 4b, it is effective to reduce the height of the Schottky barrier. Therefore, in a case where the main carriers of the current are electrons as in the n-type transistor of this embodiment, or in a case where the majority carriers in the semiconductor region 3 in which the transistor is formed are holes, the Fermi level of the source and drain regions 4a and 4b should preferably be close to the lower end of the conduction band of the semiconductor forming the semiconductor region 3. In other words, the work function of the metal or metal silicide forming the source and drain regions 4a and 4b should preferably be equal to or smaller than the difference between the center of the forbidden gap of the semiconductor forming the semiconductor region 3 and the vacuum level of the electrons.

In a case where the main carriers of the current are holes unlike those in the n-type transistor of this embodiment, or in a case where the majority carriers in the semiconductor region in which the transistor is formed are electrons, the Fermi level of the source and drain regions should preferably be close to the top end of the valence band of the semiconductor forming the semiconductor region. In other words, the work function of the metal and metal silicide forming the source and drain regions should preferably be equal to or larger than the difference between the center of the forbidden gap of the semiconductor forming the semiconductor region and the vacuum level of the electrons.

To increase the amount of current flowing through the side faces of the source and drain regions, it is possible to have the gate electrode 8 embedded between the source and drain regions 4a and 4b via the gate insulating film 7, as shown in FIG. 7. In this structure, however, the current is interfered by the gate electrode 8 existing between the source region 4a and the drain region 4b via the gate insulating film 7. This is not preferable to achieve high current driving force. Therefore, the region between the source and drain regions 4a and 4b should preferably be formed with a semiconductor.

For the same reason as above, in a structure in which the source and drain regions 4a and 4b are embedded in the substrate 1 as in this embodiment, or in which the gate insulating film 7 is formed over the source and drain regions 4a and 4b via the semiconductor layer 5, the region 6 in the semiconductor layer 5 formed on the source and drain regions 4a and 4b should preferably be formed also with a semiconductor. Furthermore, if the semiconductor forming the region 6 in the semiconductor layer 5 formed on the source and drain regions 4a and 4b is not of a single-crystalline type, the current driving force is reduced by the scattering due to the aperiodicity of the potential. Therefore, the region 6 in the semiconductor layer 5 formed on the source and drain regions 4a and 4b should preferably be formed with a single-crystalline semiconductor. The semiconductor layer 5 formed on the source and drain regions 4a and 4b should preferably be formed also with a single-crystalline semiconductor.

Next, the preferred thickness of the semiconductor layer 5 formed on the source and drain regions 4a and 4b is described. As described above, the semiconductor layer 5 should preferably be formed with a single-crystalline semiconductor. Strictly speaking, the lattice constant of the single-crystalline semiconductor depends on the type of semiconductor, but a typical semiconductor made of such a material as Si (silicon), Ge (germanium), or GaAs (gallium arsenide) has a lattice constant of approximately 0.5 nm (see “Physics of Semiconductor Devices”, S. M. Sze, John Wiley & Sons, 1981). Therefore, the thickness of the semiconductor layer 5 formed on the source and drain regions 4a and 4b should preferably be 0.5 nm or larger.

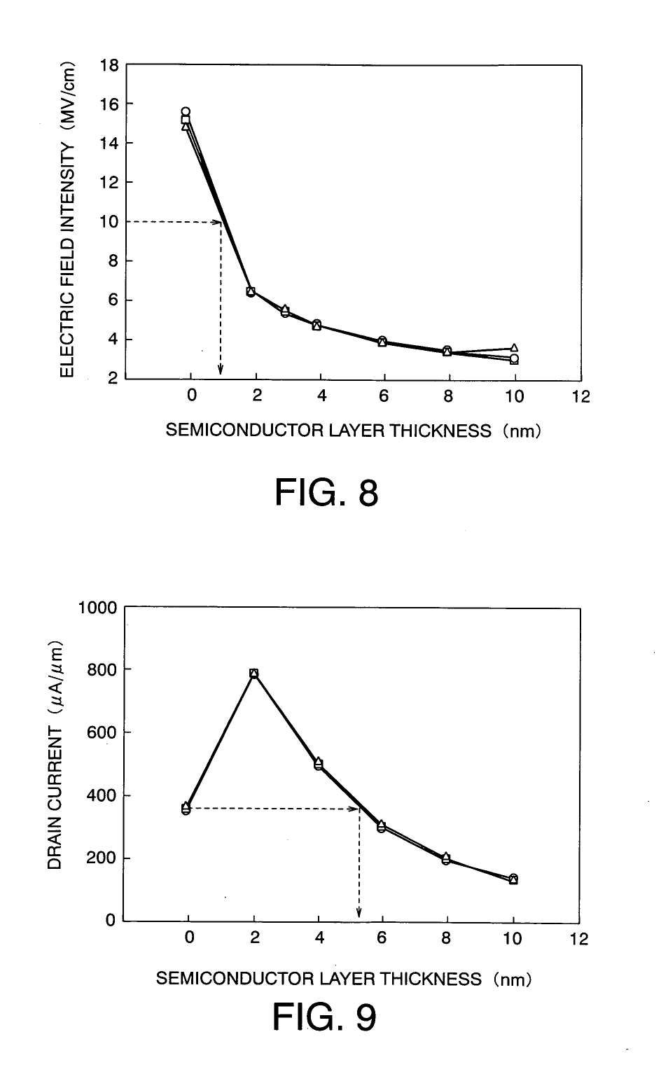

FIG. 8 shows the results of simulations performed to measure the dependence of the maximum value of the electric field intensity in the gate insulating film 7 on the thickness of the semiconductor layer 5 formed on the source and drain regions 4a and 4b. In these simulations, a Schottky field effect transistor of 35 nm in channel length was used. The gate insulating film of this transistor is a stacked film consisting of a first insulating film (an interfacial layer) made of an insulating material of 3.9 in relative permittivity on the channel side, and a second insulating film made of an insulating material of 20 in relative permittivity on the gate electrode side. While the total EOT of the gate insulating film was maintained at 1 nm, the first insulating layer (the interfacial layer) was varied from 0.3 nm, 0.4 nm, to 0.5 nm in thickness. The voltage conditions were set so that the source potential and the substrate potential were both 0 v, and the drain potential and the gate potential were both 1 V. The ordinate axis in FIG. 8 indicates the maximum value of the electric field intensity in the gate insulating film, and the abscissa axis indicates the thickness of the semiconductor layer formed on the source and drain regions. The thickness “0” of the semiconductor layer shown on the abscissa axis indicates the case of the structure shown in FIG. 2 in which the source and drain regions are not embedded. The electric field intensity hardly depends on the thickness of the interfacial layer, and dramatically decreases as the semiconductor layer is formed on the source and drain regions. This fact was also newly found by the inventor.

The electric field intensity that causes silicon oxide dielectric breakdown varies with the method of film formation, but it is typically 10 MV/cm or higher (see “Submicron Device II”, Mitsumasa Koyanagi, Maruzen Co., Ltd. 1988). Where the maximum value of the electric field intensity in the gate insulating film is required to be 10 MV/cm or lower, it can be seen from FIG. 8 that the thickness of the semiconductor layer formed on the source and drain regions should preferably be 1 nm or larger. This fact is also a fact newly found by the inventor. As is apparent from the above fact, the thickness of the semiconductor layer 5 formed on the source and drain regions 4a and 4b in this embodiment should preferably be 0.5 nm or larger, and more preferably, 1 nm or larger. This fact is also a fact newly found by the inventor.

FIG. 9 shows the dependence of the drain current on the thickness of the semiconductor layer formed on the source and drain regions. The transistor structure and the voltage conditions are the same as those in FIG. 8. The drain current hardly depends on the thickness of the interfacial layer. However, the drain current dramatically increases as the semiconductor layer is formed on the source and drain regions, and gradually decreases as the semiconductor layer becomes thicker. This fact is also a fact newly found by the inventor. Accordingly, where the drain current in this embodiment is required to be equal to or higher than the value of the drain current in the transistor of the conventional structure shown in FIG. 2, the thickness of the semiconductor layer formed on the source and drain regions should preferably be 5 nm or smaller. This fact was also newly found through the study conducted for the present invention.

In this embodiment, a p-type Schottky field effect transistor can be obtained by changing the conductivity types of the impurities, and the same effects as those of this embodiment can be achieved. This embodiment can also be applied to a complementary Schottky field effect transistor.

### Second Embodiment

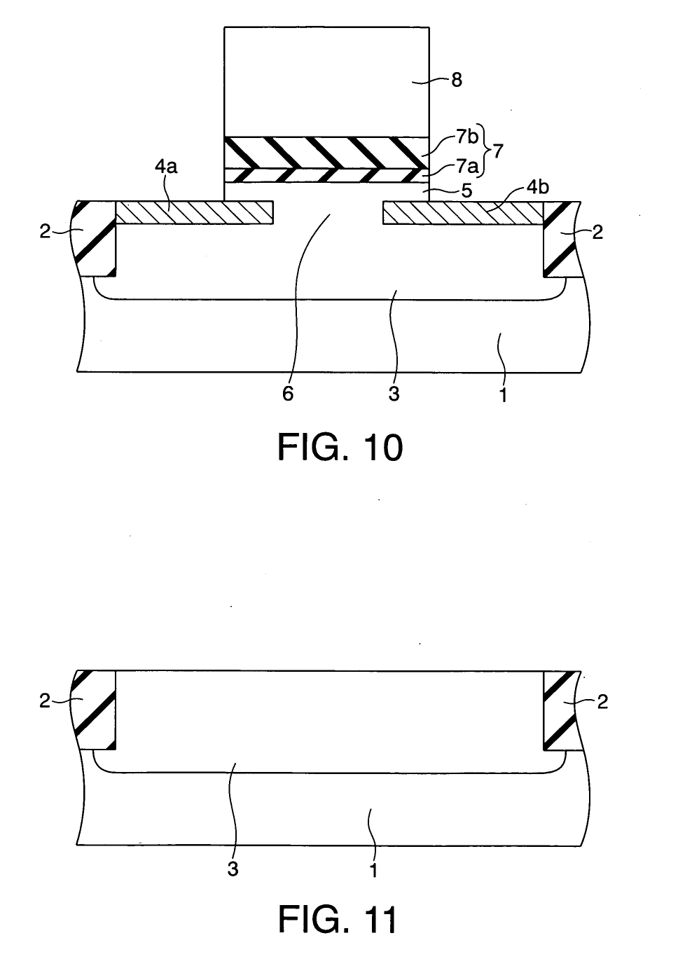

FIG. 10 is a cross-sectional view of a semiconductor device according to a second embodiment of the present invention. The semiconductor device of this embodiment is an n-type Schottky field effect transistor.

The semiconductor device of this embodiment is the same as the semiconductor device of the first embodiment shown in FIG. 1, except that the portions of the semiconductor layer 5 on both sides of the gate electrode 8 are removed. Accordingly, like the semiconductor device of the first embodiment, the semiconductor device of this embodiment includes an insulating film 7 having a stacked structure consisting of an insulating film 7a made of a low permittivity material and an insulating film 7b made of a high permittivity material. The gate insulating film 7 is formed over source and drain regions 4a and 4b via the semiconductor layer 5. In this manner, the source and drain regions 4a and 4b are embedded, and the gate electrode 8 has regions overlapping the source and drain regions 4a and 4b. In FIG. 10, an interlayer insulating film and wires are not shown.

As in the first embodiment, the resistance of the source and drain regions 4a and 4b is low in this embodiment. Thus, a Schottky field effect transistor that can restrict the electric field in the gate insulating film and can achieve high current driving force can be obtained. The insulating film 7a made of silicon oxide or the like can improve the interface with the substrate, and also can restrict a decrease in current driving force due to the capacitive coupling between the channel region 6 and the source region 4a via the gate insulating film 7. The insulating film 7b made of a high permittivity material can restrict the current flowing through the gate insulating film, and can also increase the controllability of the gate electrode 8 over the potential of the channel region 6. Accordingly, the electric field in the gate insulating film can be restrained, and even higher current driving force can be achieved. Thus, a high-performance semiconductor device that can operate at a high speed and exhibit high reliability can be obtained.

The semiconductor region 3 is formed by implanting B (boron) ions, for example, into the semiconductor substrate 1, and the source and drain regions 4a and 4b are made of erbium silicide, for example. The insulating film 7a is made of a low permittivity material such as silicon oxide, and the insulating film 7b is made of a high permittivity material such as hafnium dioxide, for example. The gate electrode 8 is made of polycrystalline silicon including P (phosphorus), for example.

Referring now to FIGS. 11 to 15, a method of manufacturing the semiconductor device of this embodiment is described.

First, as shown in FIG. 11, device isolating regions 2 are formed in the semiconductor substrate 1 by a trench device isolating method, for example. B ions are then implanted with a dose amount of 2.0×10¹² cm⁻² at an accelerating voltage of 100 keV, followed by a 30-second heat treatment at 1050° C., for example. In this manner, the semiconductor region 3 containing p-type impurities is formed.

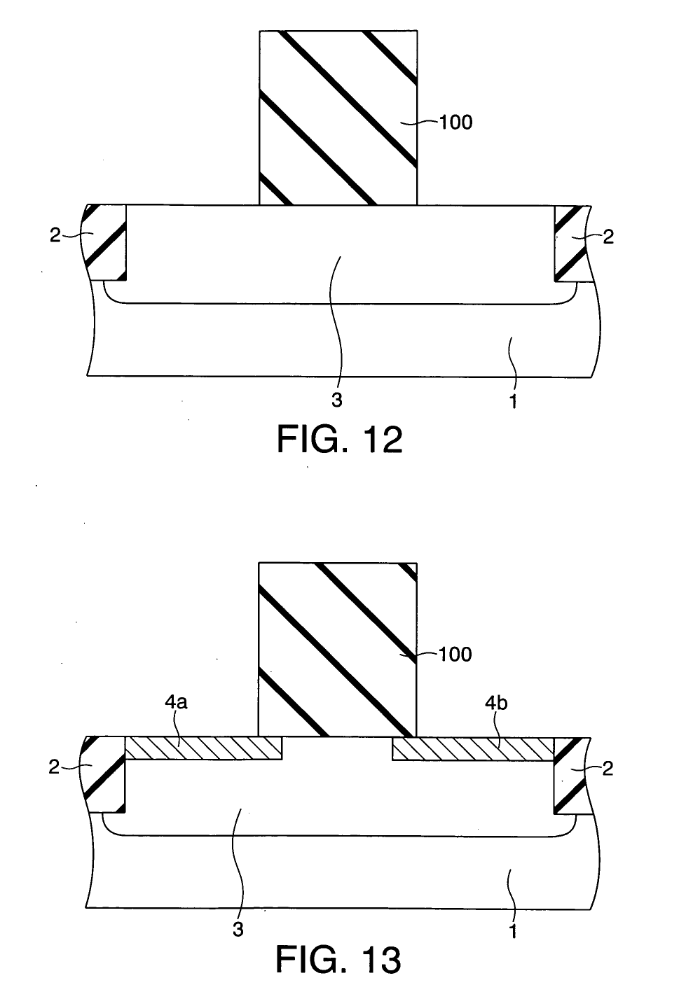

Next, as shown in FIG. 12, a silicon nitride component of 100 nm in thickness, for example, is formed by the chemical vapor deposition method (hereinafter referred to as the CVD method) or the like. A dummy gate electrode 100 is then formed by processing the silicon nitride component.

As shown in FIG. 13, erbium (Er), for example, is deposited on the entire surface of the semiconductor substrate 1 including the device isolating regions 2 and the dummy gate electrode 100 by a sputtering method or the like. A heat treatment is then carried out on the deposited erbium, so as to form the source and drain regions 4a and 4b made of erbium silicide on the surface of the semiconductor substrate 1. The unreacted portion of Er is removed by immersing the semiconductor substrate 1 in a chemical or the like.

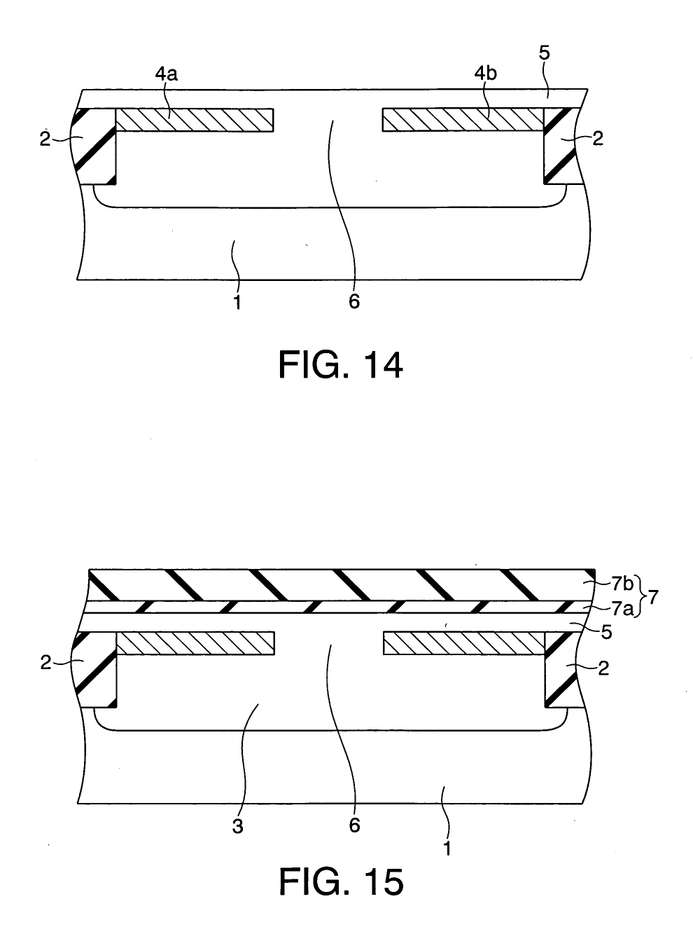

The dummy gate electrode 100 is then removed by immersing it in a chemical or the like, as shown in FIG. 14. The semiconductor layer 5 of 2 nm in thickness is then formed on the surface of the semiconductor substrate 1 including the device separating regions 2 and the source and drain regions 4a and 4b by the CVD method or the like. To achieve a desired threshold voltage, B ions are implanted with a dose amount of 1.0×10¹² cm⁻² at an accelerating voltage of 30 keV, for example. Thus, the n-channel region 6 is formed. The semiconductor layer 5 may be crystallized after the formation. Through crystallization, the scattering by the aperiodicity of potential can be restrained, and the carrier mobility is increased, accordingly. Furthermore, high current driving force can be achieved.

A silicon oxide film 7a of 1 nm in thickness, for example, is then formed by the CVD method or the like, as shown in FIG. 15. A HfO₂ (hafnium dioxide) film 7b of 5 nm in thickness, for example, is formed on the silicon oxide film 7a by the CVD method or the like.

A polycrystalline silicon film containing P (phosphorus), for example, is then formed with a thickness of 100 nm on the hafnium dioxide film 7b by the CVD method or the like. The polycrystalline silicon film is patterned by anisotropic etching such as the reactive ion etching method (hereinafter referred to as the RIE method), so as to form the gate electrode 8. The hafnium dioxide film 7b and the silicon oxide film 7a are also patterned by anisotropic etching such as the RIE method, so as to form the gate insulating film 7 with a stacked structure. The semiconductor layer 5 is then patterned by anisotropic etching such as the RIE method, so as to obtain the semiconductor device shown in FIG. 10. The procedures to be carried out thereafter to complete the semiconductor device of this embodiment are conventional procedures for forming an interlayer insulating film and wires and the like.

Although the semiconductor device of this embodiment is an n-type Schottky field effect transistor, a p-type Schottky field effect transistor can be obtained by changing the conduction types. With such a p-type Schottky field effect transistor, the same effects as those of this embodiment can be achieved. Also, the structure of this embodiment can be applied to a complementary Schottky field effect transistor.

Although the procedures for forming only a Schottky field effect transistor have been described above, the above described method according to this embodiment can also be utilized to form a Schottky field effect transistor as a part of a semiconductor device including an active device such as a field effect transistor having a conventional junction source and drain, a bipolar transistor, or a single-electron transistor, a passive device such as a resistor, a diode, an inductor, or a capacitor, or a device using a ferroelectric material or a device using a magnetic material. The method may also be utilized to form a Schottky field effect transistor as a part of an OEIC (Opto-Electrical Integrated Circuit) or a MEMS (Micro Electro Mechanical System).

In this embodiment, P (phosphorus) is used as the impurities to form an n-type semiconductor layer, and B (boron) is used as the impurities to form a p-type semiconductor layer. However, an n-type semiconductor layer may be formed with some other V-group impurities. Also, a p-type semiconductor layer may be formed with some other III-group impurities. The introduction of V-group or III-group impurities may be carried out with a compound containing V-group or III-group impurities. Where a compound semiconductor is used, impurities of some other group may be employed.

Although the introduction of impurities is carried out through ion implantation, some other method such as solid-phase diffusion or vapor-phase diffusion may be employed. Alternatively, a semiconductor containing impurities may be deposited or grown. Also, the gate electrode is formed by depositing a semiconductor containing impurities in this embodiment. However, the introduction of impurities may be carried out by some other method such as solid-phase diffusion or vapor-phase diffusion. As a semiconductor containing impurities is deposited, the impurities can be introduced at high concentration. This is advantageous in that the resistance is lowered. The ion implanting technique is also advantageous in that the procedures for forming a complementary device including an n-type transistor and a p-type transistor can be simplified.

Although Er is used to form the silicide layer for producing the source and drain regions in this embodiment, some other metal may be used. However, the Fermi level of the source and drain regions of an n-type transistor should preferably be close to the value of the lower end of the conduction band of the semiconductor used for the substrate. In view of this, in a case where a silicon substrate is employed as the substrate, the source and drain regions 4a and 4b should preferably be made of Er, a rare earth, or a metal silicide including such a material as Ti (titanium), Zr (zirconium), Hf (hafnium), Ta (tantalum), Nb (niobium), or Al (aluminum).

On the other hand, the Fermi level of the source and drain regions of a p-type transistor should preferably be close to the value of the upper end of the valence band of the semiconductor used for the substrate. In view of this, where a silicon substrate is employed as the substrate, the source and drain regions 4a and 4b should preferably be made of a metal silicide including such a material as Pt (platinum), Pd (palladium), Ir (iridium), Re (rhenium), Ru (ruthenium), or W (tungsten).

In a case where a complementary device that includes both an n-type transistor and a p-type transistor is produced, the production procedures can be advantageously simplified by forming both the n-type and p-type transistors with a material having its Fermi level in the vicinity of the center of the forbidden gap of the semiconductor serving as the substrate. In view of this, where a complementary device having its substrate made of silicon is produced, the source and drain regions 4a and 4b should preferably be made of a metal silicide containing such a material as Ni (nickel) or Co (cobalt).

Also, the source and drain regions may be made of metal, instead of silicide. In such a case, the resistance of the source and drain regions is advantageously lowered further. If the source and drain regions are made of silicide as in this embodiment, the source and drain regions can easily be formed in a self-aligning manner in relation to the dummy gate electrode and the device isolating regions, and accordingly, the production procedures can be advantageously simplified. In the case where the source and drain regions are formed with metal layers, instead of silicide layers, the preferred types of metals are the same as in the case where the source and drain regions are formed with silicide layers.

Although the introduction of impurities into the region to be turned into the source and drain regions has not been described in this embodiment, impurities may be introduced into the region to be turned into the source and drain regions. More particularly, high-concentration impurities of the opposite conductivity type to that of the channel region may be introduced into the regions to be turned into the source and drain regions. By doing so, the Schottky barrier formed at the interface between the channel region and the source and drain regions is made thinner, which is advantageous in lowering the resistance.

Although a Schottky field effect transistor is produced in this embodiment, a field effect transistor that is not of a Schottky type and has the source and drain regions formed with a semiconductor containing impurities, instead of metal silicide layers, may be produced.

Also, a device is formed on a conventional substrate or a bulk substrate in this embodiment. However, it is also possible to form a device on a SOI substrate. The impurity concentration in the channel region in the case where a device is formed on a SOI substrate may be set so that the device becomes either a complete depletion type device or a partial depletion type device. If the impurity concentration is set so as to produce a complete depletion type device, the impurity concentration in the channel region is restricted to a low value, and the mobility increases accordingly. Also, the current driving performance is improved, and the parasitic bipolar effect can be advantageously restrained.

Although not described in this embodiment, the semiconductor forming the substrate may be a IV-group semiconductor such as silicon or germanium, or a compound semiconductor made of such a compound as GaAs (gallium arsenide) or InP (indium phosphor). Alternatively, it may be a compound semiconductor made of three or more kinds of elements.

Also, the gate electrode is made of polycrystalline silicon in this embodiment. However, the gate electrode may be formed with a semiconductor made of such a material as single-crystalline silicon or non-crystalline silicon, a refractory metal or a metal not necessarily having a high melting point, a compound containing metal, or a stacked layer structure of those materials. Where the gate electrode is made of a metal or a compound containing a metal, the gate resistance is restricted, and a high-speed device operation can be advantageously performed accordingly. Furthermore, if the gate is made of a metal, oxidizing reaction is restrained, and the controllability at the interface between the gate insulating film and the gate electrode can be advantageously increased. Where a semiconductor such as polycrystalline silicon is used for at least a part of the gate electrode, the work function can be readily controlled, so that the threshold voltage of the device can also be readily adjusted.

In this embodiment, the electrode is exposed through the upper portion of the gate electrode. However, an insulating film made of silicon oxide, silicon nitride, or silicon oxynitride may be formed on the upper portion of the gate electrode. Especially, where the gate electrode is formed with a material containing a metal, or where the gate electrode needs to be protected during the production process, it is essential that a protection material such as silicon oxide, silicon nitride, or silicon oxynitride is provided on the upper portion of the gate electrode.

Also, in this embodiment, the gate electrode is formed by performing anisotropic etching after a gate electrode material is deposited. However, the gate electrode may be formed by an embedding technique such as a damascene process.

Although the lengths of the upper portion and the lower portion of the gate electrode in the principal direction of the current flowing through the device are the same in this embodiment, this is not an essential aspect of this embodiment. For example, the gate electrode may have a T-like shape, with the upper portion being longer than the lower portion. In this case, the gate resistance can also be advantageously lowered.

Although the insulating film (the interfacial film) located closer to the semiconductor layer in the gate insulating film having a stacked structure is formed with a silicon oxide film in this embodiment, this is not an essential aspect of this embodiment, and the insulating film may be formed with a silicon nitride film or a silicon oxynitride film. However, the capacitive coupling caused between the source region and the channel region by the lines of electric force penetrating the gate insulating film should be restricted to increase the current driving force. Therefore, the interfacial film should preferably have a low permittivity. Also, if the interfacial film is made of silicon oxide, the carrier mobility is increased. As a result, the current driving performance can be further increased advantageously. Since fewer charges and levels are desired in the insulating film and at the interface with the semiconductor layer, it is preferable to employ a silicon oxide film as the film to be in contact with the semiconductor layer.

Meanwhile, in a case where a semiconductor containing impurities is used for the gate electrode, the impurities in the gate electrode need to be prevented from diffusing in the channel region. Since it is a known fact that nitrogen restricts diffusion of impurities, a silicon nitride film or a silicon oxynitride film should preferably be used as the interfacial film. The interfacial film made of silicon nitride or silicon oxynitride can be formed through film deposition. In a case where silicon is employed for the semiconductor layer, the interfacial film can be formed by exposing the semiconductor layer to an oxygen or nitrogen gas in a temperature rising state, or to an oxygen or nitrogen gas that is not in a temperature rising state. The exposure to an oxygen or nitrogen gas in an excited state that does not involve a temperature rise is preferred, because a change in the concentration distribution of the impurities in the channel region due to the impurities diffusion can be prevented in this manner. Further, in a case where a silicon oxynitride film is employed, a silicon oxide film is first formed, and nitrogen is introduced into the insulating film by exposing the silicon oxide film to a gas containing nitrogen that is in a temperature rising state or an excited state. If the silicon oxynitride film is formed by exposing the insulating film to a nitrogen gas in an excited state that does not involve a temperature rise, the concentration distribution of the impurities in the channel region can be advantageously prevented from changing due to diffusion. Also in the case where a silicon oxynitride film is employed, a silicon nitride film may be formed first, and oxygen is then introduced into the insulating film by exposing the silicon nitride film to a gas containing oxygen in a temperature rising state or an excited state. If the silicon oxynitride film is formed by exposing the silicon nitride film to an oxygen gas in an excited state that does not involve a temperature rise, the concentration distribution of the impurities in the channel region can be advantageously prevented from changing due to diffusion.

Also, a HfO₂ film formed by the CVD method is employed as the insulating film located closer to the gate electrode in the gate insulating film having a stacked structure in this embodiment. However, it is also possible to employ another hafnium oxide with a different valence of Hf, a metal oxide containing Zr (zirconium), Ti (titanium), Sc (scandium), Y (yttrium), Ta (tantalum), Al (aluminum), La (lanthanum), Ce (cerium), Pr (praseodymium), or lanthanoid series elements, a silicate material containing silicon as well as various elements including the above elements, an insulating film containing nitrogen in addition to those elements, a high permittivity film, or a stacked structure of those films. With the use of such a high permittivity material, a large film thickness in a geometric sense can be set, so as to obtain a desired equivalent oxide thickness. Accordingly, the gate current can be advantageously restricted, while the high controllability of the gate electrode over the potential of the channel region can be maintained. In view of this, a high permittivity film is particularly effective in a case where a material such as a metal oxide having a higher permittivity than a silicon oxide film used for the gate insulating film in a conventional device is employed. Furthermore, the existence of nitrogen is preferred, because crystallization and deposition of particular elements can be prevented. The existence of nitrogen in the insulating film is also advantageous in that the impurities contained in a semiconductor employed as the gate electrode can be prevented from diffusing into the substrate. The method of forming the insulating film is not limited to the CVD method, and some other method such as a deposition method, a sputtering method, or an epitaxial growth method may be employed. In a case where an oxide containing a substance is employed as the insulating film, it is possible that a film of the substance is first formed, and the film is then oxidized.

In this embodiment, the gate insulating film is a stacked structure consisting of a high permittivity material and a low permittivity material. With this structure, the gate current can be advantageously restrained while the controllability of the gate electrode over the potential of the channel region can be maintained. Also, with this structure, the capacitive coupling between the source region and the channel region via the gate insulating film can be restrained, and a decrease in current driving force can be advantageously prevented. Furthermore, the gate insulating film can be designed to have a smaller film thickness in a geometric sense than in a case where the gate insulating film is formed only with a high permittivity material. Accordingly, the controllability of the gate electrode over the potential of the channel region can be prevented from decreasing due to leakage of electric force lines from the gate electrode to the outside through the side faces of the gate insulating film.

Although the gate insulating film is a two-layer stacked film in this embodiment, it may be a stacked film of three or more layers.

The thicknesses of the insulating films forming the gate electrode or the like are not limited to the values defined in this embodiment. Also, although the insulating films in the gate insulating film have the same thicknesses in this embodiment, this is not an essential aspect of this embodiment.

Although sidewalls of the gate electrode of this embodiment have not been described above, the gate electrode or the dummy gate electrode may have sidewalls. If the source and drain regions are formed without sidewalls as in this embodiment, higher controllability can be achieved over the extension length of the source and drain regions beneath the gate electrode, or the overlapping length between the source and drain regions and the gate electrode. Sidewalls can also prevent electric short-circuiting between the gate electrode and the source and drain regions at the time of formation of the source and drain regions.

Although the device isolation is carried out by the trench device isolating technique in this embodiment, it may be carried out by some other technique such as local oxidation or a mesa-type device isolating method.

Although post-oxidation performed after the formation of the gate electrode has not been mentioned in the description of this embodiment, a post-oxidizing procedure may be carried out if possible, with the materials of the gate electrode and the gate insulating film being taken into consideration. Instead of post-oxidation, an operation of rounding the corners of the lower end of the gate electrode may be performed by carrying out a chemical process or exposing it to a reactive gas. These procedures are preferred, because the electric field at the corners of the lower end of the gate electrode can be weakened through the procedures.

An interlayer insulating film has not been mentioned in the description of this embodiment either. However, it is possible to employ a material such as a low permittivity material other than silicon oxide for the interlayer insulating film. With the permittivity of the interlayer insulating film being low, the parasitic capacitance of the device becomes also low. Thus, a high-speed operation can be performed by the device.

Contact holes to be formed in the interlayer insulating film for connecting to the source and drain regions and the gate electrode have not been mentioned in the description of this embodiment, either. However, self-aligning contacts may be formed. With the self-aligning contacts, the device area can be reduced, and a higher integration degree can be advantageously achieved.

Although not mentioned in the description of this embodiment, the formation of a metal layer for wirings may be carried out by a method such as a sputtering method or a deposition method. Alternatively, such a metal layer may be formed by a selective metal growth method or a damascene method. The material for the wiring metal may be an Al (aluminum) material containing silicon, or a metal such as Cu (copper). Cu is particularly preferable, having a low resistivity.

Although each of the structures that have been described above is of a single device, this embodiment is not limited to single-device structures, and can of course achieve the same effects as above even when applied to other types of structures.

### Third Embodiment

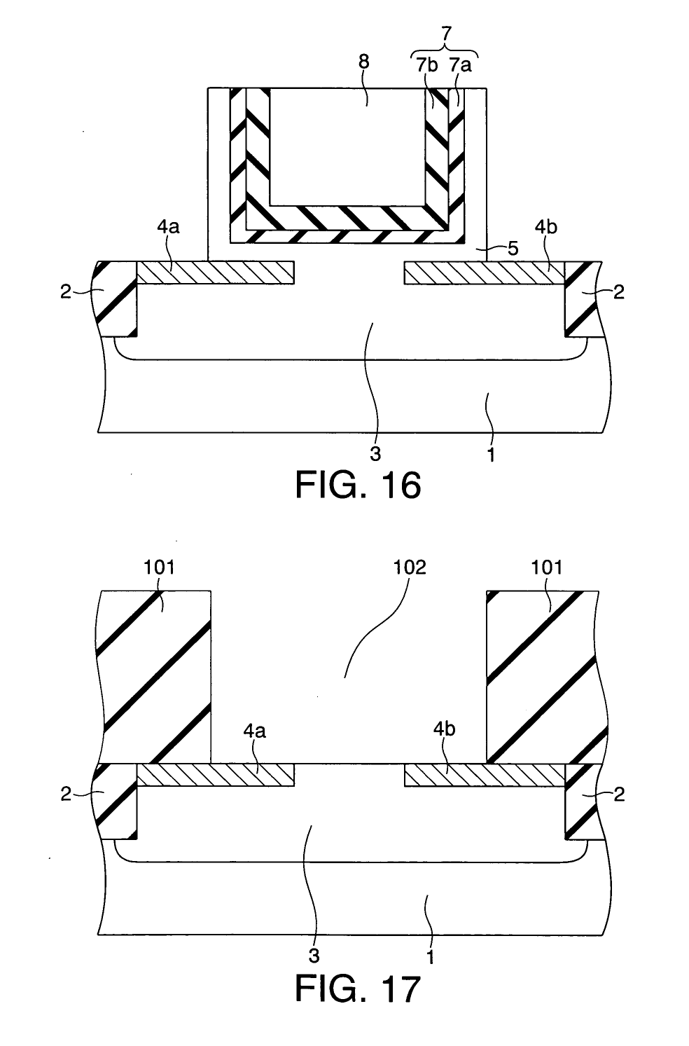

FIG. 16 is a cross-sectional view of a semiconductor device according to a third embodiment of the present invention. The semiconductor device of this embodiment differs from the semiconductor device of the second embodiment shown in FIG. 10, in that the insulating film 7b, the insulating film 7a, and the semiconductor layer 5 also cover the side portions of the gate electrode 8. In the semiconductor device of this embodiment, the gate insulating film 7 is designed to surround the gate electrode 8, and the semiconductor layer 5 is designed to surround the gate insulating film 7. In FIG. 16, the interlayer insulating film and wirings are not shown, as in FIG. 10.

Referring now to FIGS. 17 to 19, a method of manufacturing the semiconductor device of this embodiment is described.

The procedures up to the formation of the source and drain regions 4a and 4b shown in FIG. 13 are the same as those of the second embodiment. After the dummy gate electrode is formed, a silicon oxide film 101 of 200 nm in thickness, for example, is formed by the CVD method or the like, as shown in FIG. 17. The surface of the silicon oxide film 101 is smoothened by a chemical mechanical polishing (CMP) technique or the like, so as to expose the upper face of the dummy gate electrode 100. The dummy gate electrode 100 is then removed by performing a chemical process or the like, so as to form an opening 102 (see FIG. 17) in the silicon oxide film 101 in which a gate electrode is to be formed. Alternatively, an opening that is wider than the dummy gate electrode 100 may be formed in the silicon oxide film 101 by forming sidewalls on the dummy gate electrode 100 before the formation of the silicon oxide film 101, or by removing a part of the silicon oxide film 101 after the removal of the dummy gate electrode 100. By doing so, the overlapping regions between the gate electrode 8 and the source and drain regions 4a and 4b become larger, and the current driving force increases accordingly. However, without such a process, the production procedures can remain simpler.

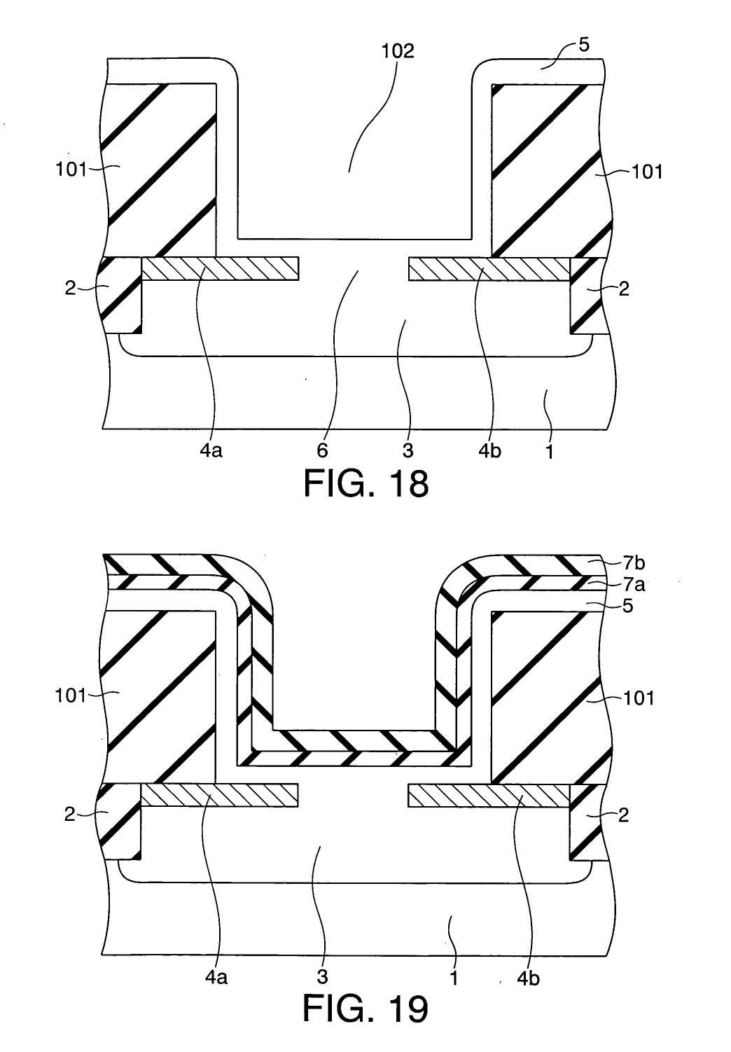

As shown in FIG. 18, a semiconductor layer 5 of 2 nm in thickness, for example, is formed on the surface of the semiconductor substrate 1 including the silicon oxide film 101 and the source and drain regions 4a and 4b by the CVD method or the like. To obtain a desired threshold voltage, B ions are implanted with a dose amount of 1.0×10¹² cm⁻² and at an accelerating voltage of 30 keV, for example. By doing so, an n-channel region 6 is formed. Crystallization may be performed after the formation of the semiconductor layer 5. Scattering due to the aperiodicity of the potential can be restrained through the crystallization, and the carrier mobility increases accordingly. As a result, a higher driving force can be advantageously achieved.

A silicon oxide film 7a of 1 nm in thickness, for example, is then formed by the CVD method or the like, as shown in FIG. 19. A HfO₂ (hafnium dioxide) film 7b of 5 nm in thickness, for example, is then formed on the silicon oxide film 7a by the CVD method or the like.

A 100-nm thick polycrystalline silicon film containing P (phosphorus), for example, is then formed on the hafnium dioxide film 7b by the CVD method or the like, followed by a treatment such as CMP. By doing so, the polycrystalline silicon film, the hafnium dioxide film 7b, the silicon oxide film 7a, and the semiconductor layer 5 are patterned to form the gate electrode 8 and the gate insulating film 7 having a stacked structure. The interlayer insulating film forming procedure and the wiring procedure are then carried out as in a conventional case, so as to obtain the semiconductor device of this embodiment shown in FIG. 16.

As in the second embodiment, the electric field in the gate insulating film can be restrained, and a higher current driving force can be achieved in this embodiment. As a result, a high-performance semiconductor device that can operate at a high speed and exhibits high reliability can be obtained.

A device manufactured according to this embodiment has the advantage that the gate electrode and the source and drain regions are formed in a self-aligning manner. On the other hand, a device manufactured according to the second embodiment has the advantage that the parasitic capacitance of the device is reduced, as the semiconductor layer 5 formed over the source and drain regions 4a and 4b does not exist on the side faces of the gate electrode 8.

In this embodiment, the film 101 that surrounds the dummy gate electrode and forms an opening in the region of the gate electrode is made of silicon oxide, some other material may be employed to form this film 101.

Also, this film 101 may be used as an interlayer insulating film or a part of an interlayer insulating film. By using the film 101 as an interlayer insulating film or a part of an interlayer insulating film, the removal does not need to be performed, and the production procedures can be advantageously simplified. On the other hand, in the case where the film 101 is removed and an interlayer insulating film is then formed, more freedom is allowed in the selection of the materials. For example, a low permittivity material may be advantageously employed to reduce the parasitic capacitance.

The various changes and modifications that can be made to the first and second embodiments as described above may also be made to this embodiment, to achieve the same effects as the above described effects.

### Fourth Embodiment

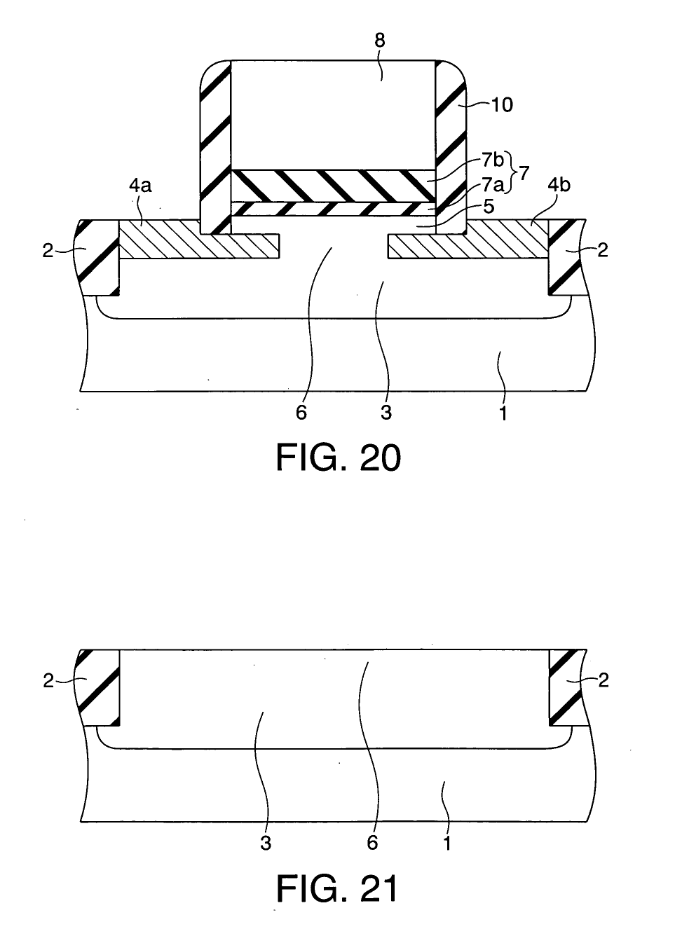

FIG. 20 is a cross-sectional view of a semiconductor device according to a fourth embodiment of the present invention. This semiconductor device has the same structure as the semiconductor device of the second embodiment shown in FIG. 10, except that the semiconductor device is formed on a semiconductor substrate 1 having a {111} plane, the overlapping regions between the gate electrode 8 and the source and drain regions 4a and 4b are located lower than the surface of the semiconductor substrate 1, and gate sidewalls 10 formed with silicon oxide films are formed on the side portions of the gate electrode 8. As in FIG. 10, an interlayer insulating film and wirings are not shown in FIG. 20. It should be noted that a {111} plane refers to a (111) plane, a (11-1) plane, a (1-11) plane, or a (−111) plane. A (11-1) plane, a (1-11) plane, and a (−111) plane are equivalent to a (111) plane in terms of crystallography.

Referring now to FIGS. 21 to 25, a method of manufacturing the semiconductor device of this embodiment is described.

As shown in FIG. 21 that illustrates the procedure following the procedure of the second embodiment shown in FIG. 11, to achieve a desired threshold voltage, B ions are implanted with a dose amount of 1.0×10¹² cm⁻² at an accelerating voltage of 30 keV, for example. Thus, an n-channel region 6 is formed.

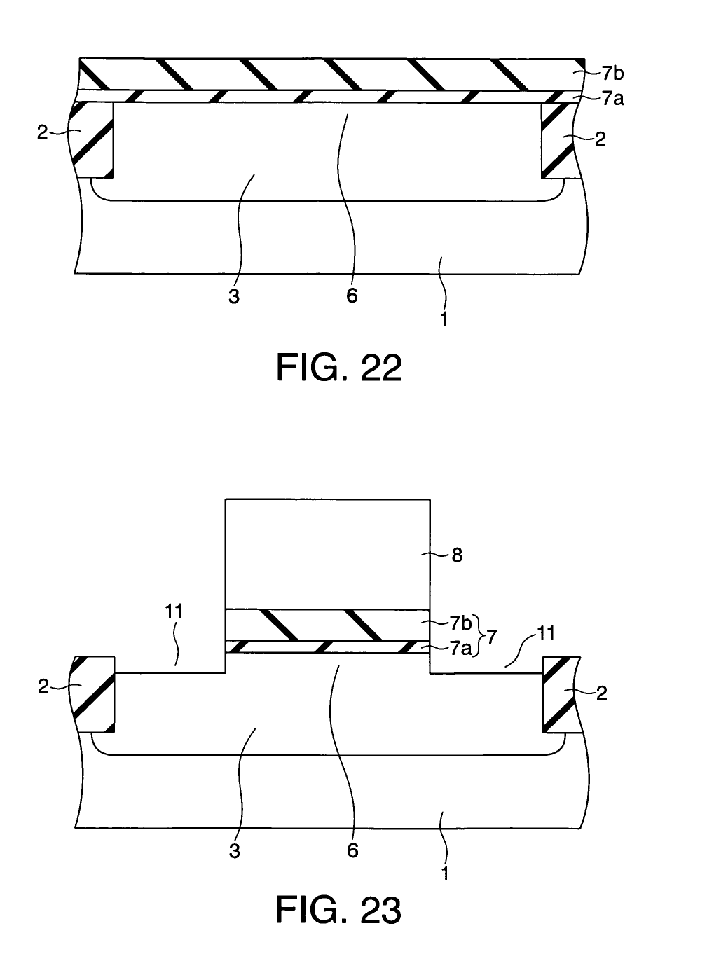

A silicon oxide film 7a of 1 nm in thickness, for example, is then formed by the CVD method or the like, as shown in FIG. 22. A HfO₂ (hafnium dioxide) film 7b of 5 nm in thickness, for example, is then formed on the silicon oxide film 7a by the CVD method or the like.

As shown in FIG. 23, a 100-nm thick polycrystalline silicon film containing P (phosphorus), for example, is then formed on the hafnium dioxide film 7b by the CVD method or the like, followed by an anisotropic etching process such as RIE. By doing so, the polycrystalline silicon film is patterned to form the gate electrode 8. The hafnium dioxide film 7b and the silicon oxide film 7a are then patterned to form the gate insulating film 7 having a stacked structure by performing anisotropic etching such as RIE. The portions of the surface of the semiconductor substrate 1 located on both sides of the gate electrode 8 are then selectively removed by performing anisotropic etching such as RIE. Thus, concavities 11 are formed (see FIG. 23).

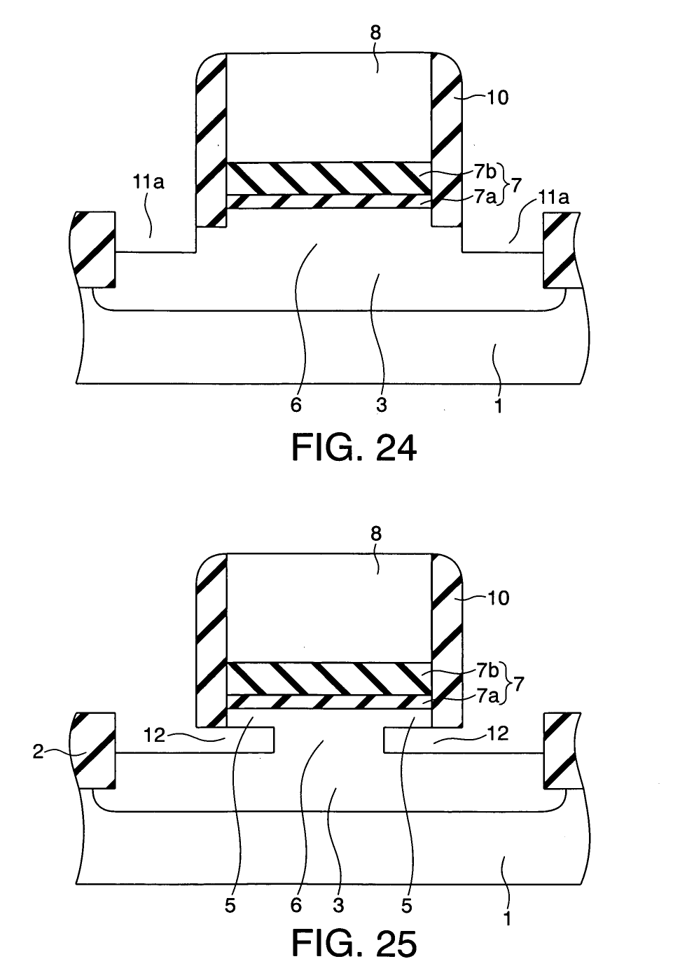

As shown in FIG. 24, a silicon oxide film of 20 nm in thickness, for example, is then formed by the CVD method or the like. Anisotropic etching such as RIE is then performed to form gate sidewalls 10. The bottom portions of the concavities 11 of the semiconductor substrate 1 are then selectively removed by performing further anisotropic etching such as RIE. Thus, even deeper concavities 11a are formed.

As shown in FIG. 25, anisotropic etching is performed on the semiconductor substrate 1 by immersing it in an alkaline solution, for example. With an alkaline solution, the speed of etching a (111) plane and any plane equivalent to a (111) plane in terms of crystallography is very low. Therefore, substantial etching is not caused, and the semiconductor substrate 1 is not possibly etched in the vertical direction in FIG. 25. As a result, etching is caused in the transverse direction, and the semiconductor layer 5 remains under the gate insulating film 7. Voids 12 are formed in the etched regions of the semiconductor layer 5, and such a structure as schematically shown in FIG. 25 is obtained.

A metal or a metal silicide is then deposited to fill the voids 12 formed in the semiconductor substrate 1. The deposited metal or metal silicide is partially removed to form the source and drain regions 4a and 4b. Thus, the semiconductor device shown in FIG. 20 is obtained. The interlayer insulating film forming procedure and the wiring procedure are carried out thereafter by the conventional techniques, so as to complete the semiconductor device of this embodiment.

As in the second embodiment, the electric field in the gate insulating film can be restrained, and a higher current driving force can be achieved in this embodiment. Accordingly, a high-performance semiconductor device that can operate at a high speed and exhibits high reliability can be obtained.

A device manufactured according to this embodiment has the advantage that the gate electrode 8 and the source and drain regions 4a and 4b are formed in a self-aligning manner. Furthermore, since the channel region 6 is formed in the semiconductor substrate 1, a good single-crystalline structure can be advantageously achieved.

On the other hand, in a case where a device is manufactured according to any of the first to third embodiments, a substrate having a given plane can be employed as the semiconductor substrate. Accordingly, an optimum substrate can be selected, with the other characteristics such as the carrier mobility being taken into consideration. Thus, a higher degree of freedom is advantageously allowed in the selection of the material for the semiconductor substrate.

Although the gate sidewalls 10 are formed with silicon oxide films in this embodiment, some other material may be employed. However, silicon oxide with a low permittivity has the advantage that the parasitic capacitance of the device can be reduced. In a case where the gate sidewalls 10 are formed with silicon nitride films, the gate sidewalls 10 can be protected from etching, even when a hydrofluoric acid treatment that is often used in a conventional semiconductor device manufacturing process and is therefore well known its characteristics is carried out so as to remove a natural oxide film formed on the surface of the semiconductor substrate 1 before the formation of the source and drain regions 4a and 4b.

Etching is performed on the source and drain regions 4a and 4b by immersing them in an alkaline solution in this embodiment. However, some other technique may be utilized. For example, the technique of immersing an object in an alkaline solution such as a KOH (potassium hydroxide) solution or a TMAH (Tetra Methyl Ammonium Hydroxide) solution is well known for its characteristics and is often used in a conventional semiconductor device manufacturing process. Accordingly, this technique has the advantage that the procedure involving this technique can be readily controlled.

The upper faces of the source and drain regions 4a and 4b are located at the same height as the surface of the semiconductor substrate 1 in this embodiment. However, this is not an essential aspect of this embodiment, and the same effects as above can be achieved even if the upper faces of the source and drain regions 4a and 4b are not located at the same height as the surface of the semiconductor substrate 1.

The various changes and modifications that can be made to the first to third embodiments as described above may also be made to this embodiment, to achieve the same effects as the above described effects.

### Fifth Embodiment

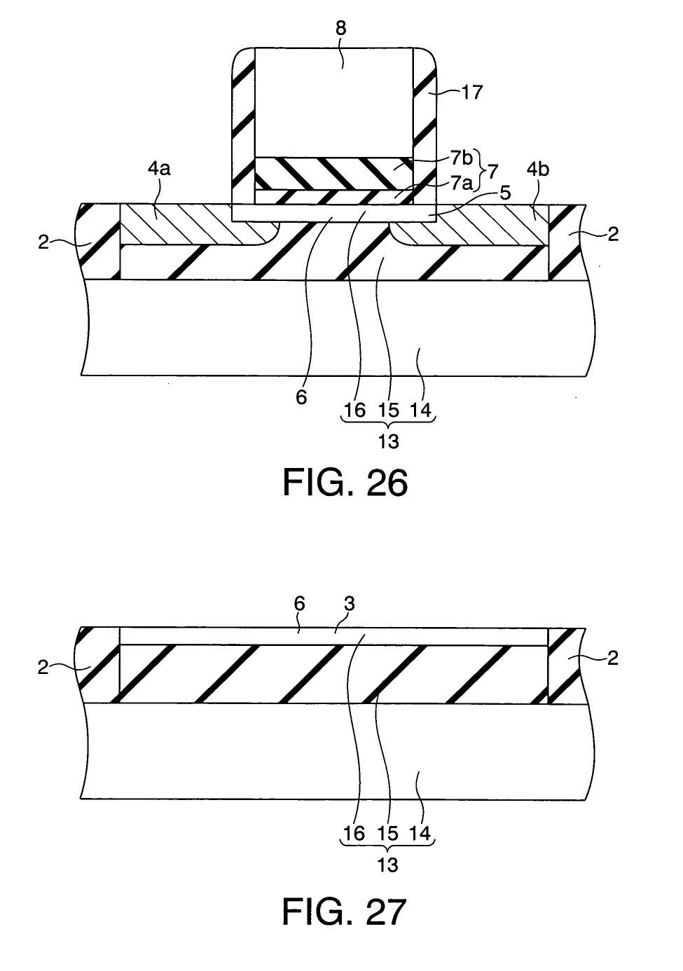

FIG. 26 is a cross-sectional view of a semiconductor device according to a fifth embodiment of the present invention. The semiconductor device of this embodiment has the same structure as the semiconductor device of the fourth embodiment shown in FIG. 20, except that the semiconductor device is formed on a semiconductor substrate (a SOI substrate) 13 having a semiconductor layer 16 on a supporting substrate 14 via an insulating film 15, and the source and drain regions 4a and 4b are located lower than the semiconductor layer 16. It should be noted that the gate sidewalls 17 formed on the side portions of the gate electrode 8 are made of silicon nitride, instead of silicon oxide. In FIG. 26, an interlayer insulating film and wirings are not shown.

Next, a method of manufacturing the semiconductor device of this embodiment is described.

As shown in FIG. 27, device isolating regions 2 are first formed in the SOI substrate 13 by a trench device isolating method or the like. B ions are then implanted in the semiconductor layer 16 with a dose amount of 2.0×10¹² cm⁻² at an accelerating voltage of 100 keV, followed by a 30-second heat treatment at 1050° C., for example. In this manner, a semiconductor region 3 containing p-type impurities is formed. To achieve a desired threshold voltage, B ions are implanted with a dose amount of 1.0×10¹² cm⁻² at an accelerating voltage of 30 keV, for example. Thus, an n-channel region 6 is formed.

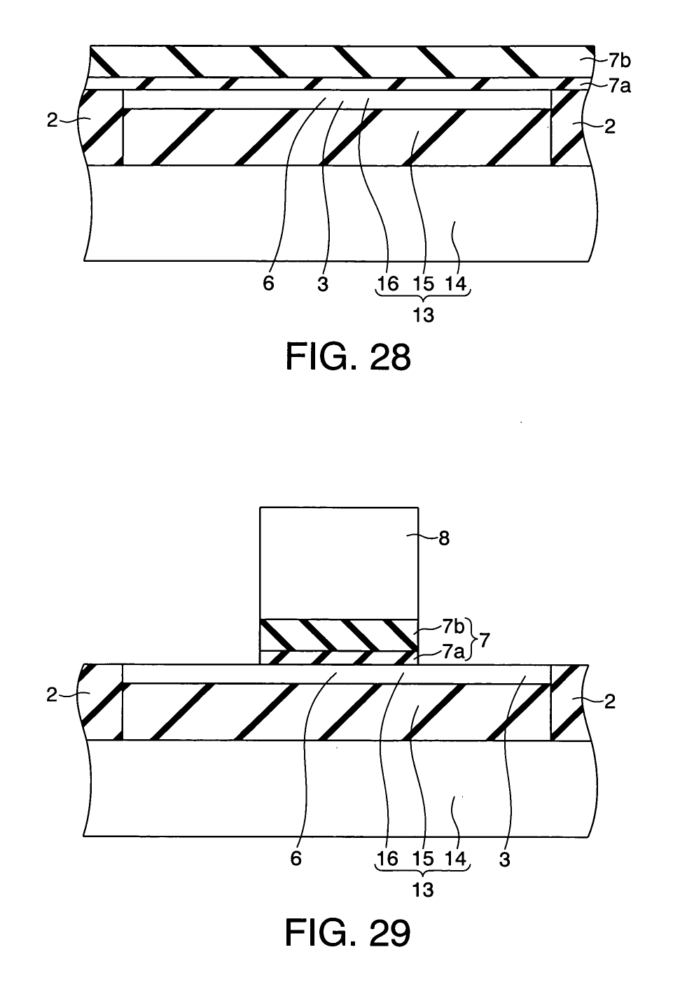

A silicon oxide film 7a of 1 nm in thickness, for example, is then formed by the CVD method or the like, as shown in FIG. 28. A HfO₂ (hafnium dioxide) film 7b of 5 nm in thickness, for example, is then formed on the silicon oxide film 7a by the CVD method or the like.

As shown in FIG. 29, a 100-nm thick polycrystalline silicon film containing P (phosphorus), for example, is then formed on the hafnium dioxide film 7b by the CVD method or the like, followed by an anisotropic etching process such as RIE. By doing so, the polycrystalline silicon film is patterned to form the gate electrode 8. Anisotropic etching such as RIE is then performed on the hafnium dioxide film 7b and the silicon oxide film 7a, so as to form the gate insulating film 7 having a stacked structure.

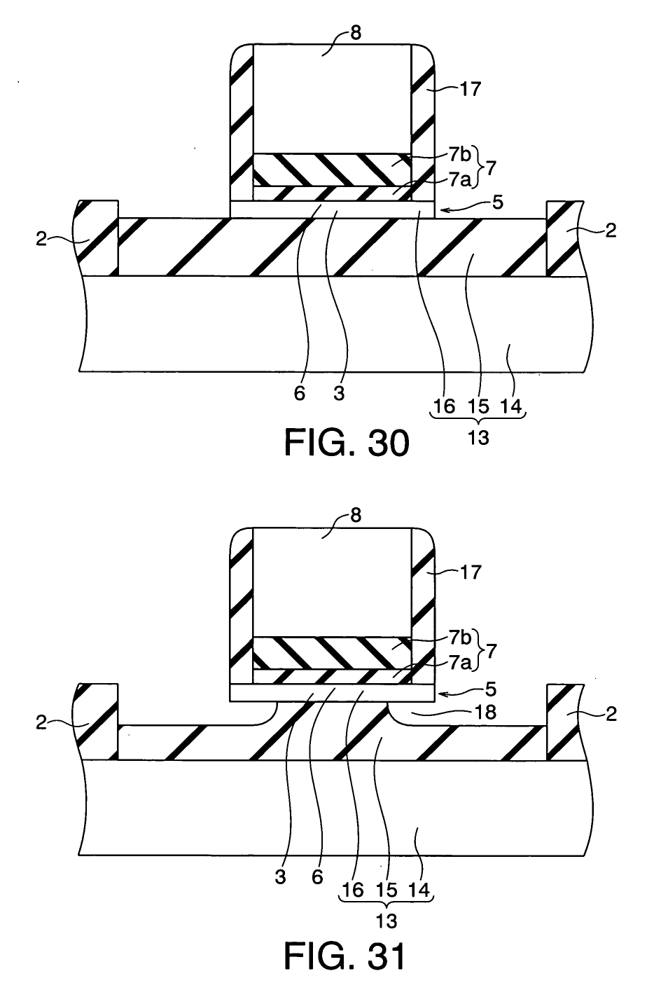

As shown in FIG. 30, a silicon nitride film of 20 nm in thickness, for example, is then formed by the CVD method or the like. Anisotropic etching such as RIE is then performed on the silicon nitride film, so as to form the gate sidewalls 17. Anisotropic etching such as RIE is further performed to partially remove the semiconductor layer 16, so as to form the semiconductor layer 5 on the source and drain.

As shown in FIG. 31, the insulating film 15 is immersed in a hydrofluoric acid solution or the like, and is partially removed to form voids 18. At the same time, the device isolating regions 2 may also be partially removed.

A metal or a metal silicide is then deposited to fill the voids 18 formed in the insulating film 15. The deposited metal or metal silicide is partially removed to form the source and drain regions 4a and 4b. The interlayer insulating film forming procedure and the wiring procedure are carried out thereafter by the conventional techniques, so as to complete the semiconductor device of this embodiment.

As described above, the electric field in the gate insulating film can be restrained, and a higher current driving force can be achieved in this embodiment. Accordingly, a high-performance semiconductor device that can operate at a high speed and exhibits high reliability can be obtained.

A device manufactured according to this embodiment has the advantage that the gate electrode 8 and the source and drain regions 4a and 4b are formed in a self-aligning manner. Furthermore, since the channel region 6 is formed in the SOI substrate 13, a good single-crystalline structure can be advantageously achieved. Also, this embodiment has the advantage that a layer having a given plane can be employed as the semiconductor layer 16 to form the device.

On the other hand, a device manufactured according to any of the first to fourth embodiments has the advantage that the wiring structure for controlling the potential of the substrate is easy.

Although the gate sidewalls 17 are formed with silicon nitride films in this embodiment, some other material may be employed. However, since silicon nitride cannot be etched with hydrofluoric acid, it has the advantage that the gate insulating film and the gate electrode can be effectively protected from etching with hydrofluoric acid in the later stages. On the other hand, gate sidewalls made of silicon oxide have the advantage that the parasitic capacitance of the device can be reduced, as silicon oxide has a low permittivity.

Although the thickness of the semiconductor layer 16 is not varied in this embodiment, it may be varied. Particularly, the thickness of each portion of the semiconductor layer 16 located above the source and drain regions 4a and 4b may be made thinner than the portion of the semiconductor layer 16 located in the region between the source and drain regions 4a and 4b. With this arrangement, the thickness of the Schottky barrier formed on each upper face of the source and drain regions 4a and 4b can be advantageously adjusted by controlling the capacitive coupling between the gate electrode 8 and the source and drain regions 4a and 4b, and the resistance of the channel region 6 can also be advantageously lowered by adjusting the thickness of the channel region 6 formed between the source and drain regions 4a and 4b.

The various changes and modifications that can be made to the first to fourth embodiments as described above may also be made to this embodiment, to achieve the same effects as the above described effects.

### Sixth Embodiment

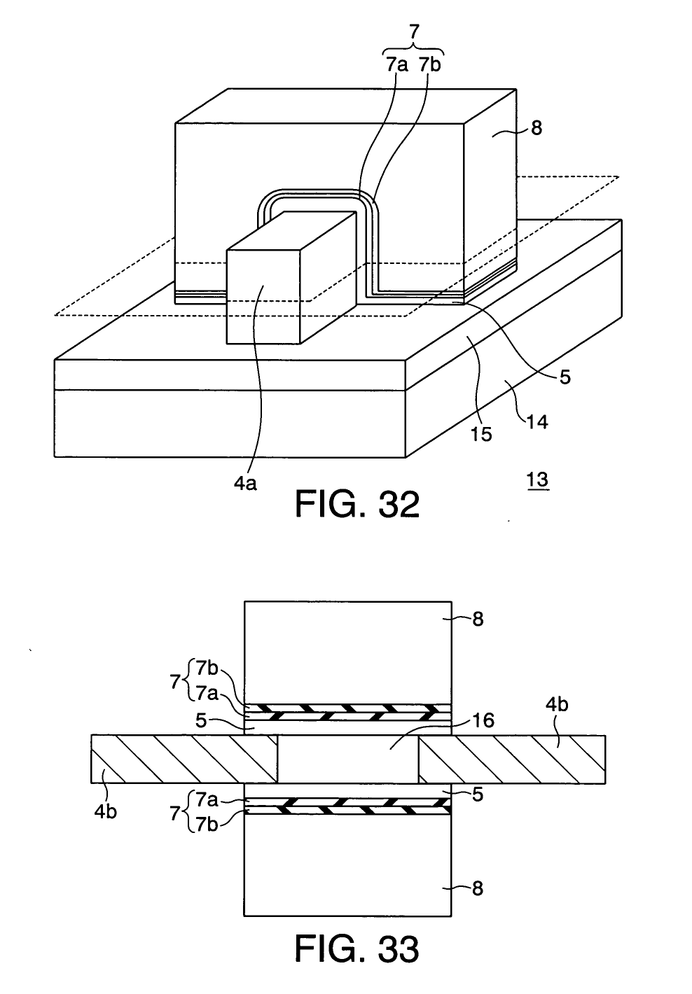

FIG. 32 is a perspective view of a semiconductor device according to a sixth embodiment of the present invention. FIG. 33 is a cross-sectional view of the semiconductor device, taken along the plane indicated by a broken line in FIG. 32. The semiconductor device of this embodiment is formed on a semiconductor substrate (a SOI substrate) 13 having a semiconductor layer 16 provided on a supporting substrate 14 via an insulating film 15. The semiconductor layer 16 is processed to form the region between the source and drain regions 4a and 4b (see FIG. 33). The source and drain regions 4a and 4b and the region in between form into a rectangular parallelepiped. Here, a rectangular parallelepiped may be a plate-like structure having a thickness smaller than the height, or a plate-like structure having a thickness larger than the height. A gate insulating film 7 that is a stacked structure formed with an insulating film 7a made of a low permittivity material and an insulating film 7b made of a high permittivity material is formed over the source and drain regions 4a and 4b via a semiconductor layer 5. A gate electrode 8 is then formed over the gate insulating film 7, and sandwiches the source and drain regions 4a and 4b at both sides. Although not shown in FIG. 32, the source and drain regions 4a and 4b also exist behind the gate electrode 8. Here, an interlayer insulating film and wirings are not shown.

Next, a method of manufacturing the semiconductor device of this embodiment is described.

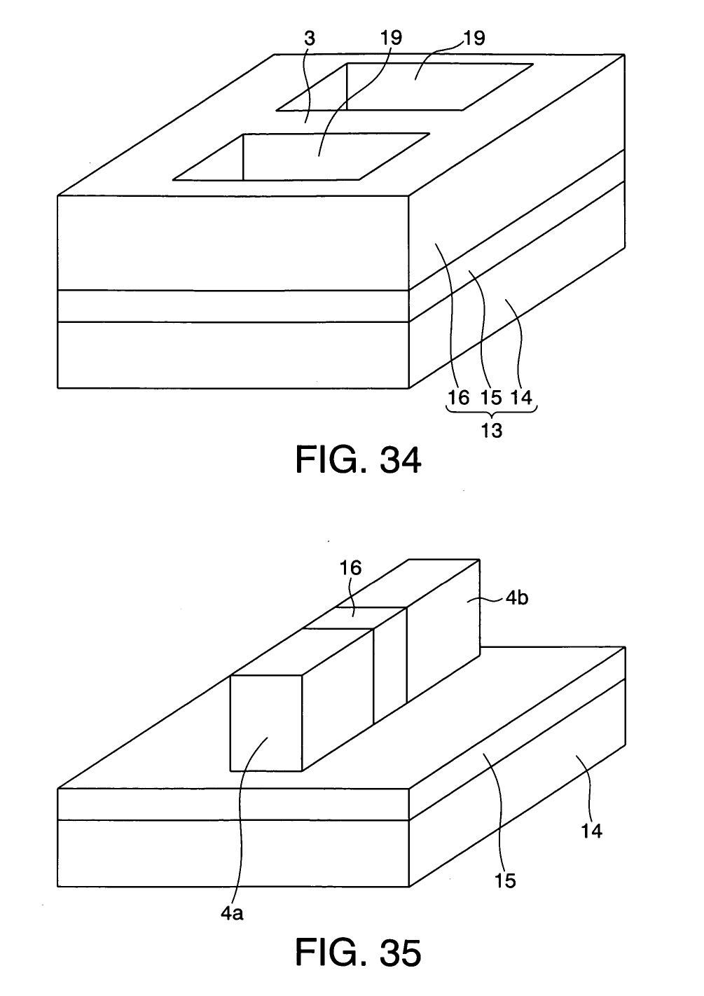

As shown in FIG. 34, B (boron) ions are first implanted in the p-well formation region of the SOI substrate 13 with a dose amount of 2.0×10¹² cm⁻² at an accelerating voltage of 100 keV, followed by a 30-second heat treatment at 1050° C., for example. In this manner, the semiconductor region 3 containing p-type impurities is formed. Anisotropic etching such as RIE is then performed on the semiconductor layer 16, so as to form voids 19 in the regions in and around which the source and drain regions are to be formed.

A metal or a metal silicide is then deposited to fill the voids 19 formed in the semiconductor layer 16, as shown in FIG. 35. The semiconductor layer 16 and the deposited metal or metal silicide is partially removed, so as to form the source and drain regions 4a and 4b and the semiconductor region 16 in between.

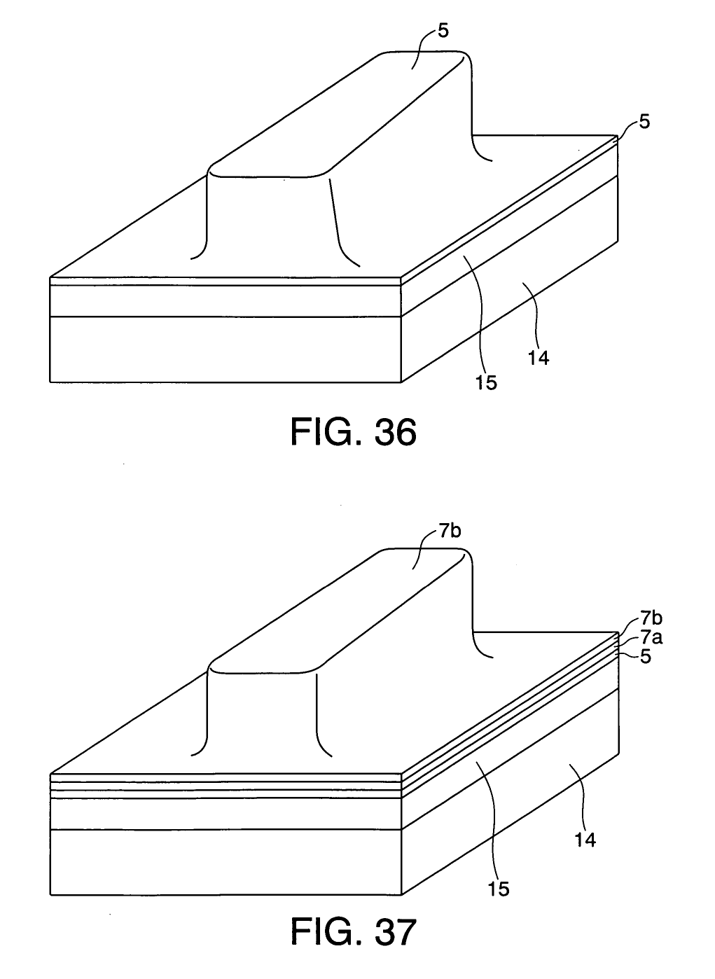

As shown in FIG. 36, the semiconductor layer 5 of 2 nm in thickness, for example, is then formed on the surface of the semiconductor substrate 13 including the source and drain regions 4a and 4b and the region 16 in between by the CVD method or the like. Crystallization may be performed after the formation of the semiconductor layer 5. Through the crystallization, scattering due to the aperiodicity of the potential can be restrained, and the carrier mobility increases accordingly. As a result, an even higher current driving force can be achieved.

As shown in FIG. 37, a silicon oxide film 7a of 1 nm in thickness, for example, is then formed by the CVD method or the like. A HfO₂ (hafnium dioxide) film 7b of 5 nm in thickness, for example, is then formed on the silicon oxide film 7a by the CVD method or the like.

A 100-nm thick polycrystalline silicon film containing P (phosphorus), for example, is then formed on the hafnium dioxide film 7b by a deposition technique such as the CVD method, followed by an anisotropic etching process such as RIE. By doing so, the polycrystalline silicon film is patterned to form the gate electrode 8. Anisotropic etching such as RIE is then performed on the hafnium dioxide film 7b and the silicon oxide film 7a, so as to form the gate insulating film 7 having a stacked structure. Anisotropic etching such as RIE is further performed to process the semiconductor layer 5. The interlayer insulating film forming procedure and the wiring procedure are carried out thereafter by the conventional techniques, so as to complete the semiconductor device of this embodiment.

In a device manufactured according to this embodiment, the areas in the source and drain regions 4a and 4b facing the gate electrode 8 via the semiconductor layer 5 and the gate insulating film 7 are larger than in any case of the first to fifth embodiments. As mentioned in the description of the first embodiment, a high current driving force can be achieved, because the Schottky barrier formed on the plane in the source and drain regions 4a and 4b facing the gate electrode 8 is made thinner, and its resistance is lowered. Accordingly, as the areas in the source and drain regions 4a and 4b facing the gate electrode 8 are increased, an even higher current driving force can be advantageously achieved.

On the other hand, a structure according to any of the first to fifth embodiments has the advantage that its manufacturing process is simpler than that in this embodiment.

Also, the thicknesses of the semiconductor layer 5 and the gate insulating film 7 formed between the gate electrode 8 and the source and drain regions 4a and 4b are the same on the upper face and the side faces in this embodiment. However, this is not an essential aspect of this embodiment, and the thickness of the gate insulating film formed on the side faces may be different from the thickness of the gate insulating film formed on the upper face. Also, the thickness of the gate insulating film located may be varied between a flat region and the vicinity of a convex region in the region located above the source and drain regions and the semiconductor region in between. Particularly, the thickness of the gate insulating film in the vicinity of a convex portion is preferably made larger than the thickness of the gate insulating film in the flat region, so that the electric field intensity in the insulating film in the vicinity of the convex portion can be advantageously restrained, as disclosed in Japanese Patent Application (No. 2004-273509), filed by the applicant.

Also, the gate electrode 8 facing the upper faces and the side faces of the source and drain regions 4a and 4b and the semiconductor region 16 in between is a single component in this embodiment. However, this is not an essential aspect of this embodiment, and separate gate electrodes may be provided on both sides.

Also, the source and drain regions 4a and 4b and the semiconductor region 16 in between are thinner in the transverse direction, and are sandwiched by the gate electrode 8 at both sides. However, this is not an essential aspect of this embodiment, and the source and drain regions 4a and 4b and the semiconductor region 16 may be thinner in the vertical direction, and may be sandwiched at the top and the bottom. Where the source and drain regions 4a and 4b and the semiconductor region 16 in between are thinner in the transverse direction and are sandwiched at both sides as in this embodiment, the gate electrodes on both sides can be readily aligned with each other. With this arrangement, even a single gate electrode can be advantageously employed as in this embodiment.

In a case where the source and drain regions 4a and 4b and the semiconductor region 16 in between are thinner in the vertical direction and are sandwiched by the gate electrode 8 at the top and the bottom, on the other hand, a device that is thinner in the vertical direction than the structure of this embodiment. Accordingly, flattening in a later stage can be performed easier.

Although not performed in this embodiment, impurity implantation for adjusting the threshold voltage may also be performed. This embodiment has the advantage that the manufacturing process is simplified, because impurities are implanted during the formation of the semiconductor layer 5 on the source and drain regions 4a and 4b. However, impurity implantation performed in some other stage than the film forming procedure brings about the advantage that the threshold voltage can be fine-adjusted.

As described above, the electric field in the gate insulating film can be restrained, and a high current driving force can be achieved in this embodiment. As a result, a high-performance semiconductor device that can operate at a high speed and exhibits high reliability can be obtained.

The various changes and modifications that can be made to the first to fifth embodiments as described above may also be made to this embodiment, to achieve the same effects as the above described effects.

### Seventh Embodiment

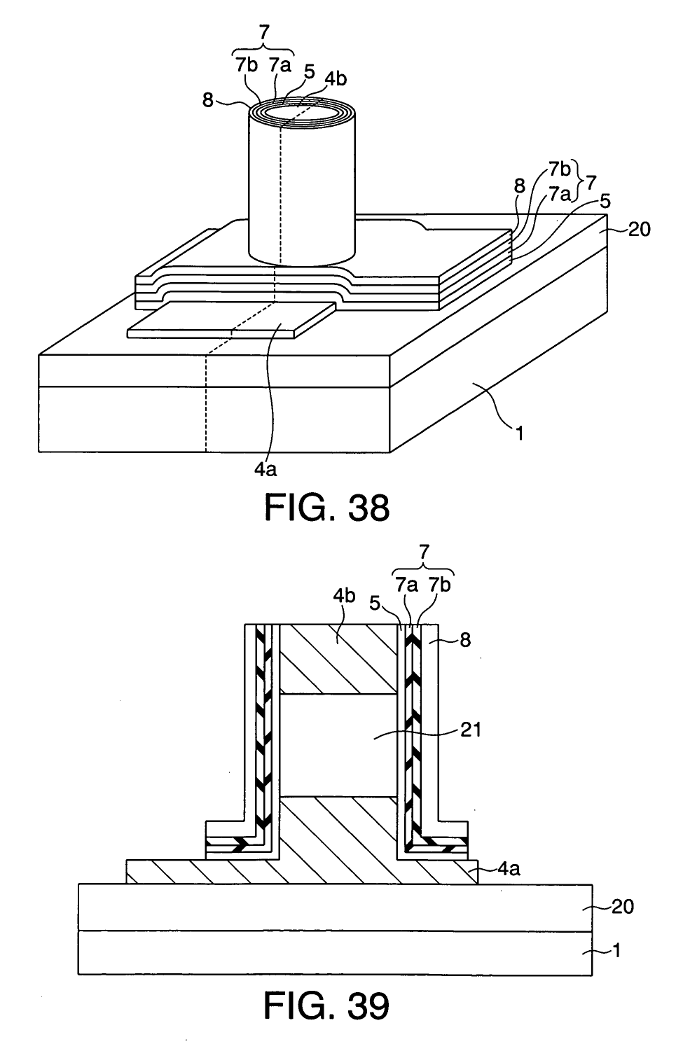

FIG. 38 is a perspective view of a semiconductor device according to a seventh embodiment of the present invention. FIG. 39 is a cross-sectional view of the semiconductor device, taken along the plane indicated by the broken line in FIG. 38. The semiconductor device of this embodiment is formed on an insulating film 20 made of silicon oxide or the like that is formed on a semiconductor substrate 1. In this semiconductor device, a semiconductor region 21 is formed in the region between the source and drain regions 4a and 4b. The source and drain regions 4a and 4b and the semiconductor region 21 in between form into a pillar-like structure. A gate insulating film 7 is formed to surround the source and drain regions 4a and 4b and the semiconductor region 21 via the semiconductor layer 5. The gate insulating film 7 is a stacked structure consisting of an insulating film 7a made of a low permittivity material and an insulating film 7b made of a high permittivity material. A gate electrode 8 is formed to surround the gate insulating film 7. Here, an interlayer insulating film and wirings are not shown. In this embodiment, the source region 4a is located closer to the semiconductor substrate 1, and the drain region 4b is located further away from the semiconductor substrate 1. However, the locations of the source and drain regions 4a and 4b may be reversed.

Next, a method of manufacturing the semiconductor device of this embodiment is described.

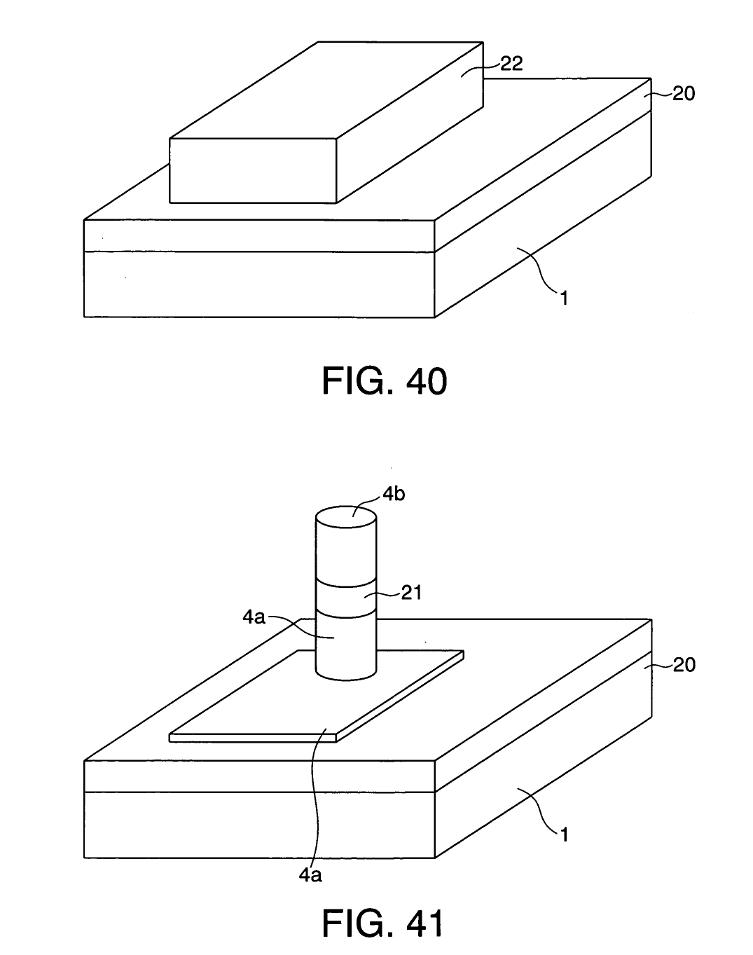

As shown in FIG. 40, a silicon oxide film 20 of 100 nm in thickness, for example, is first formed on the semiconductor substrate 1 by the CVD method or the like. A first film 22 made of a metal or a metal silicide is then formed by the CVD or the like, and processing such as RIE is performed to pattern the first film 22.

As shown in FIG. 41, a semiconductor layer 21 containing B and having a thickness of 30 nm, for example, is formed by the CVD method or the like on the first film 22 made of a metal or a metal silicide. A second film made of a metal or a metal silicide is then formed on the semiconductor layer 21 by the CVD method or the like. Crystallization may be performed after the formation of the semiconductor layer 21. Through the crystallization, scattering due to the aperiodicity of the potential can be restrained, and an even higher current driving force can be advantageously achieved. Anisotropic etching such as RIE is then performed on the second film, the semiconductor layer 21, and the first film 22, so as to pattern the second film, the semiconductor layer 21, and the first film 22 into a pillar-like form. By doing so, the source and drain regions 4a and 4b and the pillar-like semiconductor layer 21 interposed between the source and drain regions 4a and 4b are obtained. The portion of the first layer 22 to be the source region 4a is patterned into a pillar-like form on the side of the semiconductor layer 21, while the portion of the first layer 22 on the side of the insulating film 20 remains as it was before the formation of the semiconductor layer 21.

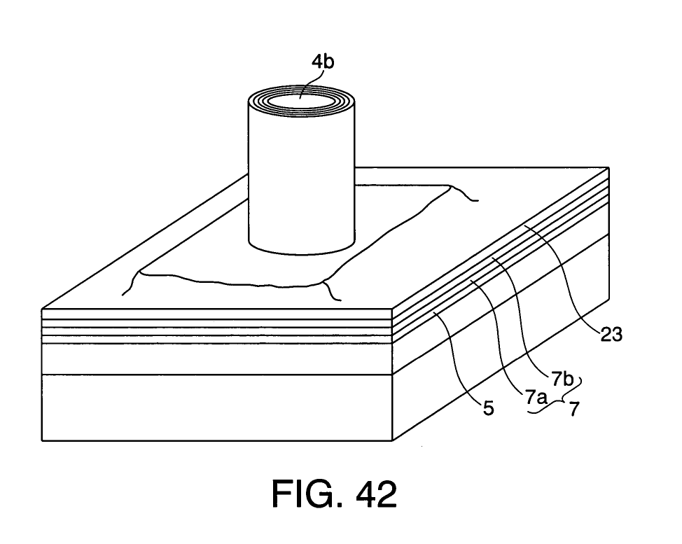

As shown in FIG. 42, a semiconductor layer 5 of 2 nm in thickness, for example, is then formed by the CVD method or the like on the surface of the semiconductor substrate 1 including the source and drain regions 4a and 4b and the semiconductor region 21 in between. Crystallization may be performed after the formation of the semiconductor layer 5. Through the crystallization, scattering due to the aperiodicity of the potential can be restrained, and the carrier mobility increases accordingly. Further, a high current driving force can be advantageously achieved. A silicon oxide film 7a of 1 nm in thickness, for example, is then formed by the CVD method or the like. A HfO₂ (hafnium dioxide) film 7b of 5 nm in thickness, for example, is further formed on the silicon oxide film 7a by the CVD method or the like. A polycrystalline silicon film 23 containing P (phosphorus) and having a thickness of 100 nm, for example, is then formed on the hafnium dioxide film 7b by the CVD method or the like. Anisotropic etching such as RIE is performed to pattern the polycrystalline silicon film 23. Thus, the gate electrode 8 is formed (see FIGS. 38 and 39).

Anisotropic etching such as RIE is further performed to pattern the hafnium dioxide film 7b and the silicon oxide film 7a. Thus, the gate insulating film 7 having a stacked structure is formed (see FIGS. 38 and 39). The semiconductor layer 5 is then patterned by anisotropic etching such as RIE. The procedures such as the interlayer insulating film forming procedure and the wiring procedure are carried out thereafter by the conventional techniques, so as to complete the semiconductor device of this embodiment.

In a device manufactured according to this embodiment, the source and drain regions 4a and 4b are surrounded by the gate electrode 8 via the semiconductor layer 5 and the gate insulating film 7, which is not the case in any of the first to sixth embodiments. As mentioned in the description of the first embodiment, a high current driving force can be achieved, because a thin Schottky barrier formed on the plane in the source and drain regions facing the gate electrode has a low resistance. As the source and drain regions 4a and 4b are surrounded by the gate electrode 8, this embodiment has the advantage that an even higher current driving force can be achieved.

Meanwhile, each of the first to sixth embodiments has the advantage that the wiring procedure is simplified, since the source and drain regions are arranged in parallel with the substrate surface.

Although the principal direction of current is perpendicular to the surface of the semiconductor substrate in this embodiment, the principal direction of current may be in parallel with the surface of the semiconductor substrate. With this arrangement, the wiring procedure is advantageously simplified, as the source and drain regions are arranged in parallel with the substrate surface. In the case where the principal direction of current is perpendicular to the surface of the semiconductor substrate as in this embodiment, the semiconductor layer 21 formed between the source and drain regions 4a and 4b does not contain a region that is hidden behind when seen from an angle perpendicular to the surface of the semiconductor substrate. Accordingly, the procedure for forming the gate electrode 8 in such a manner as to surround the source and drain regions 4a and 4b and the semiconductor layer 21 in between is advantageously simplified.

In this embodiment, the source and drain regions 4a and 4b and the semiconductor layer 21 formed in between each have a circular section in a direction perpendicular to the principal direction of current. However, this is not an essential aspect of this embodiment, and the same effects as above can be achieved with some other shapes.

Although not performed in this embodiment, impurity implantation for adjusting the threshold voltage may also be performed. This embodiment has the advantage that the manufacturing process is simplified, because impurities are implanted during the formation of the semiconductor layer 21 on the source and drain regions 4a and 4b. However, impurity implantation performed in some other stage than the film forming procedure brings about the advantage that the threshold voltage can be fine-adjusted.

As described above, the electric field in the gate insulating film can be restrained, and a high current driving force can be achieved in this embodiment. As a result, a high-performance semiconductor device that can operate at a high speed and exhibits high reliability can be obtained.

The various changes and modifications that can be made to the first to sixth embodiments as described above may also be made to this embodiment, to achieve the same effects as the above described effects.

As described so far, in any of the embodiments of the present invention, the electric field in the gate insulating film can be restrained, and the current driving force of the device can be increased. Thus, a high-performance semiconductor device that can perform high-speed operations and exhibits high reliability can be obtained.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concepts as defined by the appended claims and their equivalents.

What is claimed is:

1. A semiconductor device comprising:
a semiconductor region provided on a substrate;
source and drain regions provided in the semiconductor region at a distance from each other so as to face each other;
a semiconductor layer provided on the source and drain regions and a region interposed between the source region and the drain region;
a gate insulating film provided at least above the region interposed between the source region and the drain region so as to sandwich the semiconductor layer between the gate insulating film and the region interposed between the source region and the drain region; and
a gate electrode provided on the gate insulating film.

2. The semiconductor device as claimed in claim 1, wherein the source and drain regions are made of metal or metal silicide.

3. The semiconductor device as claimed in claim 2, wherein:
the semiconductor region has holes as majority carriers; and
a work function of the metal or the metal silicide forming the source and drain regions is equal to or smaller than the difference between the center of a forbidden gap of the semiconductor of the semiconductor substrate and a vacuum level of electrons.

4. The semiconductor device as claimed in claim 2, wherein:
the semiconductor region has electrons as majority carriers; and
a work function of the metal or the metal silicide forming the source and drain region is equal to or larger than the difference between the center of a forbidden gap of the semiconductor of the semiconductor substrate and a vacuum level of electrons.

5. The semiconductor device as claimed in claim 1, wherein the semiconductor layer has a thickness within the range of 0.5 nm to 5 nm.

6. The semiconductor device as claimed in claim 1, wherein the end portions of the source and drain regions are located partially in the semiconductor region immediately below the gate electrode.

7. The semiconductor device as claimed in claim 1, further comprising:
gate sidewalls that are provided on side portions of the gate electrode, and are made of an insulating material, bottom portions of the gate sidewalls reaching the source and drain regions below the semiconductor layer.

8. The semiconductor device as claimed in claim 7, wherein the region between the source and drain regions, and a region between a portion of the semiconductor layer located on the source region and a portion of the semiconductor layer located on the drain region are formed of a single-crystalline semiconductor.

9. The semiconductor device as claimed in claim 1, wherein:
the semiconductor region and the source and drain regions are arranged on the substrate in a direction of a principal plane of the semiconductor substrate, and form into a rectangular parallelepiped;
the semiconductor layer is provided at least on side faces of the rectangular parallelepiped of the semiconductor region and the source and drain regions;
the gate insulating film is disposed to cover an upper face of the rectangular parallelepiped and the semiconductor layer; and
the gate electrode is disposed to cover the gate insulating film.

10. The semiconductor device as claimed in claim 1, wherein:
the semiconductor region and the source and drain regions are arranged on the substrate in a direction perpendicular to a principal plane of the semiconductor substrate, and form into a pillar-like structure;
the semiconductor layer is provided at least on side faces of the pillar-like structure of the semiconductor region and the source and drain regions;
the gate insulating film is disposed to surround the semiconductor layer; and
the gate electrode is disposed to surround the gate insulating film.

11. The semiconductor device as claimed in claim 1, wherein the semiconductor layer is formed with a single-crystalline semiconductor.

12. The semiconductor device as claimed in claim 1, wherein the gate insulating film has a lower permittivity in an interface region between the gate insulating film and the semiconductor layer than a permittivity at the center of the gate insulating film.

13. The semiconductor device as claimed in claim 12, wherein the gate insulating film is a stacked film that includes a first insulating film made of one of silicon oxide, silicon oxynitride, and silicon nitride, and a second insulating film containing metal.

14. The semiconductor device as claimed in claim 1, wherein the semiconductor substrate is a substrate having a {111} plane.

15. The semiconductor device as claimed in claim 1, wherein the semiconductor substrate is a SOI substrate.

16. A semiconductor device comprising:
a first semiconductor element that comprises:
a first semiconductor region that is formed on a semiconductor substrate and contains p-type impurities;
first source and drain regions that is formed so as to face each other at a distance from each other in the first semiconductor region, and are made of a metal such as Ni (nickel) or Co (cobalt) or a metal silicide of Ni (nickel) or Co (cobalt);
a first semiconductor layer that is formed on the first source and drain regions and a region interposed between the first source region and the first drain region;
a first gate insulating film that is formed at least above the region interposed between the first source region and the first drain region so as to sandwich the first semiconductor layer between the first gate insulating film and the region interposed between the first source region and the first drain region; and
a first gate electrode that is disposed on the first gate insulating film; and
a second semiconductor element that comprises:
a second semiconductor region that is formed on a semiconductor substrate and contains n-type impurities;
second source and drain regions that is formed so as to face each other at a distance from each other in the second semiconductor region, and are made of a metal such as Ni (nickel) or Co (cobalt) or a metal silicide of Ni (nickel) or Co (cobalt);
a second semiconductor layer that is formed on the second source and drain regions and a region interposed between the second source region and the second drain region;
a second gate insulating film that is formed at least above the region interposed between the second source region and the second drain region so as to sandwich the second semiconductor layer between the second gate insulating film and the region interposed between the second source region and the second drain region; and
a second gate electrode that is disposed on the second gate insulating film.

17. A method of manufacturing a semiconductor device, comprising:
introducing either n-type impurities or p-type impurities into a semiconductor region;
forming source and drain regions at a distance from each other, so that the source and drain regions face each other in the semiconductor region into which the impurities are introduced;
forming a semiconductor layer to cover at least a region interposed between the source and drain regions;
forming a gate insulating film on the semiconductor layer; and
forming a gate electrode on the gate insulating film.

18. A method of manufacturing a semiconductor device, comprising:
introducing either n-type impurities or p-type impurities into a semiconductor region having a {111} plane;
forming a first insulating film above the semiconductor region;
forming a gate electrode at least on a part of the first insulating film;
forming a gate insulating film by removing portions of the first insulating film located on both sides of the gate electrode;
partially removing surfaces on both side faces of the gate electrode in the semiconductor region;
forming a second insulating film on both sides of the gate electrode;
forming voids by removing at least a part of the semiconductor region through anisotropic etching; and
forming source and drain regions in the voids.

19. A method of manufacturing a semiconductor device, comprising:
introducing either n-type impurities or p-type impurities into a semiconductor layer of a SOI substrate on which the semiconductor layer is formed on a supporting substrate via a first insulating film;
forming a second insulating film on the semiconductor layer;
forming a gate electrode on at least a part of the second insulating film;
removing portions of the second insulating film located on both sides of the gate electrode;
forming a third insulating film on side faces of the gate electrode;
removing portions of the semiconductor layer located on both sides of the gate electrode;
forming voids by removing at least a part of the first insulating film; and
forming source and drain regions in the voids.

20. The method as claimed in claim 17, wherein the source and drain regions are made of metal or metal silicide.
